(19) United States
(12) Patent Application Publication
(10) Pub. No.: US 2025/0227391 A1
(43) Pub. Date: Jul. 10, 2025

(54) IMAGE SENSOR HAVING NANO-PHOTONIC LENS ARRAY AND ELECTRONIC APPARATUS INCLUDING THE SAME

(71) Applicant: SAMSUNG ELECTRONICS CO., LTD., Suwon-si (KR)

(72) Inventors: Sang-eun MUN, Suwon-si (KR); Sungmo Ahn, Suwon-si (KR); Sookyoung Roh, Suwon-si (KR); Kyungbae Park, Suwon-si (KR); Sungyoung Yun, Suwon-si (KR); Younhee Lim, Suwon-si (KR)

(73) Assignee: SAMSUNG ELECTRONICS CO., LTD., Suwon-si (KR)

(21) Appl. No.: 18/984,202

(22) Filed: Dec. 17, 2024

(30) Foreign Application Priority Data
Jan. 10, 2024 (KR) 10-2024-0004348

(51) Int. Cl. H04N 25/703; H04N 25/10

(52) U.S. Cl. CPC H04N 25/703; H04N 25/10

(57) ABSTRACT

Provided is an image sensor including a sensor substrate including a plurality of pixels, a nano-photonic lens array including a plurality of nanostructures configured to separate light based on wavelength of the light and focus the light onto a corresponding pixel among the plurality of pixels, and an organic photoelectric conversion layer between the sensor substrate and the nano-photonic lens array, the organic photoelectric conversion layer being configured to absorb photons and multiply carriers.

### CROSS-REFERENCE TO RELATED APPLICATION

This application claims priority to Korean Patent Application No. 10-2024-0004348, filed on Jan. 10, 2024, in the Korean Intellectual Property Office, the disclosure of which is incorporated by reference herein in its entirety.

### BACKGROUND

### 1. Field

Example embodiments of the present disclosure relate to an image sensor having a nano-photonic lens array and an electronic apparatus including the same.

### 2. Description of Related Art

An image sensor may detect a color of incident light by using a color filter. However, because the color filter absorbs light of colors other than light of the corresponding color, light utilization efficiency may decrease. For example, when using an red-green-blue (RGB) color filter, only ⅓ of the incident light is transmitted and the remaining ⅔ is absorbed, and thus, light utilization efficiency is only about 33%. Therefore, in the case of a color display device or color image sensor, most light loss occurs in the color filter.

### SUMMARY

One or more example embodiments provide image sensors having a nano-photonic lens array and an organic photoelectric conversion layer.

One or more example embodiments also provide electronic apparatuses including the image sensor described above.

Additional aspects will be set forth in part in the description which follows and, in part, will be apparent from the description, or may be learned by practice of the presented embodiments of the disclosure.

According to an aspect of an example embodiment, there is provided an image sensor including a sensor substrate including a plurality of pixels, a nano-photonic lens array including a plurality of nanostructures configured to separate light based on wavelength of the light and focus the light onto a corresponding pixel among the plurality of pixels, and an organic photoelectric conversion layer between the sensor substrate and the nano-photonic lens array, the organic photoelectric conversion layer being configured to absorb photons and multiply carriers.

The organic photoelectric conversion layer may include a singlet fission material.

The singlet fission material may include polyacene, rylene, rubrene, biradicaloid, or any combination thereof.

The polyacene may include anthracene, tetracene, pentacene, or any combination thereof.

The rylene may include perylene, terylene, or any combination thereof.

The image sensor may further include an intermediate layer between the sensor substrate and the organic photoelectric conversion layer, the intermediate layer being configured to prevent recombination of charge-electron pairs, wherein a thickness of the intermediate layer is in a range from 1 nm to 10 nm.

The image sensor may further include a spacer layer between the organic photoelectric conversion layer and the nano-photonic lens array, wherein a thickness of the spacer layer is in a range from 500 nm to 1000 nm.

A thickness of the organic photoelectric conversion layer may be in a range from 10 nm to 100 nm.

The image sensor may further include a color filter layer between the organic photoelectric conversion layer and the spacer layer, wherein the color filter layer may include a plurality of color filters.

The plurality of color filters may be organic color filters.

The image sensor may further include a barrier wall between the plurality of color filters.

The barrier wall may extend to a certain portion of the organic photoelectric conversion layer.

The organic photoelectric conversion layer may include a plurality of organic photoelectric conversion elements, and the plurality of organic photoelectric conversion elements may have different thicknesses based on a color of a corresponding color filter.

The plurality of color filters may be inorganic color filters.

Each of the plurality of nanostructures may include a first nanostructure and a second nanostructure, and the first nanostructure and the second nanostructure may be arranged in a multi-layer structure.

The image sensor may include an anti-reflection film on the nano-photonic lens array.

According to another aspect of an example embodiment, there is provided an electronic apparatus including an image sensor configured to convert an optical image into an electrical signal, and a processor configured to control operation of the image sensor and store and output signals generated by the image sensor, wherein the image sensor may include a sensor substrate including a plurality of pixels, a nano-photonic lens array including a plurality of nanostructures configured to separate light based on wavelength of the light and focus the light onto a corresponding pixel among the plurality of pixels, and an organic photoelectric conversion layer between the sensor substrate and the nano-photonic lens array, the organic photoelectric conversion layer being configured to absorb photons and multiply carriers.

The organic photoelectric conversion layer may include a singlet fission material.

The singlet fission material may include polyacene, rylene, rubrene, biradicaloid, or any combination thereof.

The polyacene may include anthracene, tetracene, pentacene, or any combination thereof, and the rylene may include perylene, terylene, or any combination thereof.

According to still another aspect of an example embodiment, there is provided an image sensor including a sensor substrate including a plurality of pixels, a nano-photonic lens array including a plurality of nanostructures configured to separate light based on wavelength of the light and focus the light onto a corresponding pixel among the plurality of pixels, and an organic photoelectric conversion layer between the sensor substrate and the nano-photonic lens array, the organic photoelectric conversion layer including a material configured to absorb photons and increase a number of excitons.

### BRIEF DESCRIPTION OF DRAWINGS

The above and other aspects, features, and advantages of example embodiments of the disclosure will be more apparent from the following description taken in conjunction with the accompanying drawings, in which:

FIG. 1 is a block diagram of an image sensor according to an example embodiment;

FIG. 2 shows various examples of pixel arrangements of a pixel array of an image sensor;

FIGS. 3A and 3B are schematic cross-sectional views showing a configuration of a pixel array of an image sensor according to an example embodiment;

FIG. 4 is a schematic plan view showing a configuration of a sensor substrate of the pixel array shown in FIGS. 3A and 3B;

FIG. 5 is a schematic plan view showing a configuration of a color filter layer shown in FIGS. 3A and 3B;

FIG. 6 is a plan view illustrating a configuration of a nano-photonic lens array shown in FIGS. 3A and 3B;

FIG. 7 illustrates graphs showing the efficiency of an image sensor to which the pixel array of FIGS. 3A and 3B is applied;

FIG. 8 is a schematic cross-sectional view showing a configuration of a pixel array of an image sensor according to another example embodiment;

FIGS. 9A and 9B are plan views showing an example arrangement of nanostructures of the nano-photonic lens array of FIG. 8;

FIG. 10 illustrates graphs showing the efficiency of an image sensor to which the arrangement of nanostructures of the nano-photonic lens array of FIGS. 9A and 9B and a resulting organic photoelectric conversion layer are applied;

FIGS. 11A and 11B are plan views showing other example arrangements of nanostructures of the nano-photonic lens array of FIG. 8;

FIG. 12 illustrates graphs showing the efficiency of an image sensor to which the arrangement of nanostructures of the nano-photonic lens array of FIGS. 11A and 11B and a resulting organic photoelectric conversion layer are applied;

FIGS. 13, 14, and 15 are schematic cross-sectional views showing configurations of a pixel array of an image sensor according to various example embodiments;

FIG. 16 is a schematic block diagram showing an electronic apparatus including an image sensor according to an example embodiment;

FIG. 17 is a schematic block diagram showing a camera module of FIG. 16;

FIG. 18 is a block diagram of an electronic apparatus including a multi-camera module; and

FIG. 19 is a detailed block diagram of a multi-camera module of the electronic apparatus shown in FIG. 18.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, an expression, “at least one of a, b, and c” should be understood as including only a, only b, only c, both a and b, both a and c, both b and c, or all of a, b, and c.

Hereinafter, an image sensor including a nano-photonic lens array and an electronic apparatus including the image sensor will be described in detail with reference to the accompanying drawings. The example embodiments of the disclosure are capable of various modifications and may be embodied in many different forms. In the drawings, like reference numerals refer to the like elements, and sizes of components in the drawings may be exaggerated for clarity and convenience of explanation.

Hereinafter, when a position of an element is described using an expression “above” or “on”, the position of the element may include not only the element being “immediately on/under/left/right in a contact manner” but also being “on/under/left/right in a non-contact manner”.

Although the terms ‘first’, ‘second’, etc. may be used herein to describe various constituent elements, these terms are only used to distinguish one constituent element from another. These terms do not limit the difference in material or structure of the constituent elements.

The singular forms are intended to include the plural forms as well, unless the context clearly indicates otherwise. When a part “comprises” or “includes” an element in the specification, unless otherwise defined, it is not excluding other elements but may further include other elements.

Also, in the specification, the term “units” or “ . . . modules” denote units or modules that process at least one function or operation, and may be realized by hardware, software, or a combination of hardware and software.

The term “above” and similar directional terms may be applied to both singular and plural.

With respect to operations that constitute a method, the operations may be performed in any appropriate sequence unless the sequence of operations is clearly described or unless the context clearly indicates otherwise. The use of all examples or illustrative terms (e.g., “such as”) is simply for explaining the technical idea in detail, and the scope is not limited by the examples or illustrative terms unless limited by the claims.

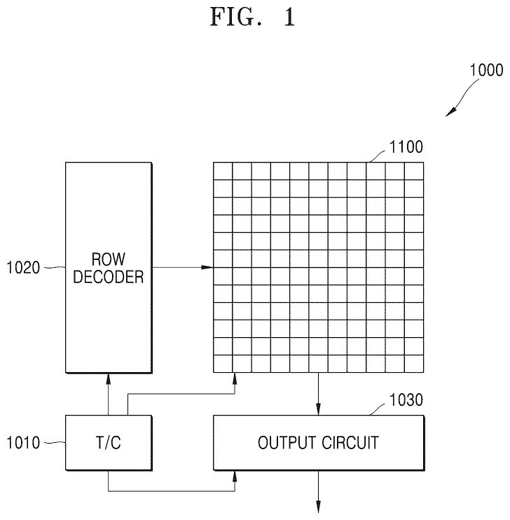

FIG. 1 is a schematic block diagram of an image sensor 1000 according to an example embodiment.

Referring to FIG. 1, the image sensor 1000 may include a pixel array 1100, a timing controller 1010, a row decoder 1020, and an output circuit 1030. The image sensor may be a charge coupled device (CCD) image sensor or a complementary metal oxide semiconductor (CMOS) image sensor.

The pixel array 1100 includes pixels arranged two-dimensionally along a plurality of rows and columns. The row decoder 1020 selects one row of the pixel array 1100 in response to a row address signal output from the timing controller 1010. The output circuit 1030 outputs a light detection signal in column units from a plurality of pixels arranged along the selected row. To this end, the output circuit 1030 may include a column decoder and an analog to digital converter (ADC). For example, the output circuit 1030 may include a plurality of ADCs arranged for each column between the column decoder and the pixel array 1100, or one ADC arranged at an output terminal of the column decoder. The timing controller 1010, the row decoder 1020, and the output circuit 1030 may be implemented as one chip or as separate chips. A processor for processing an image signal output through the output circuit 1030 may be implemented as a single chip together with the timing controller 1010, the row decoder 1020, and the output circuit 1030.

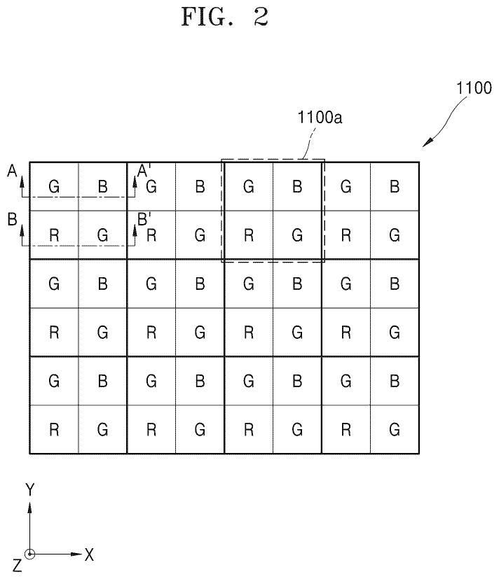

The pixel array 1100 may include a plurality of pixels that sense light of different wavelengths. The arrangement of pixels may be implemented in various ways. For example, FIG. 2 shows various pixel arrangements of the pixel array 1100 of the image sensor 1000.

First, FIG. 2 shows a Bayer pattern that is generally adopted in the image sensor 1000. Referring to FIG. 2, one unit pattern includes four quadrant regions, and the first to fourth quadrants are respectively a green pixel (G), a blue pixel (B), a red pixel (R), and a green pixel (G). These unit patterns are arranged two-dimensionally and repeatedly in a first (horizontal) direction (X direction) and a second (horizontal) direction (Y direction). For example, within a unit pattern in the form of a 2×2 array, two green pixels (G) are arranged diagonally on one side, and one blue pixel (B) and one red pixel (R) are placed diagonally on the other side. When the overall pixel arrangement is viewed, a first row in which a plurality of green pixels (G) and a plurality of blue pixels (B) are alternately arranged in the first direction, and a second row in which a plurality of red pixels (R) and a plurality of green pixels (G) are arranged alternately in the first direction are repeatedly arranged in the second direction (the Y direction). The pixel array 1100 may be arranged in various ways other than the Bayer pattern. For example, a CYGM arrangement in which magenta pixels (M), cyan pixels (C), yellow pixels (Y), and green pixels (G) form one unit pattern, or an RGBW arrangement in which green pixels (G), red pixels (R), blue pixels (B), and white pixels (W) form one unit pattern is also possible. Additionally, for example, the unit pattern may have a 3×2 array form. Additionally, pixels of the pixel array 1100 may be arranged in various ways depending on the color characteristics of the image sensor 1000. Below, it will be explained that the pixel array 1100 of the image sensor 1000 has a Bayer pattern as an example, but the operating principle may be applied to other types of pixel arrays other than the Bayer pattern.

Hereinafter, for convenience, a case when the pixel array 1100 has a Bayer pattern structure will be described as an example.

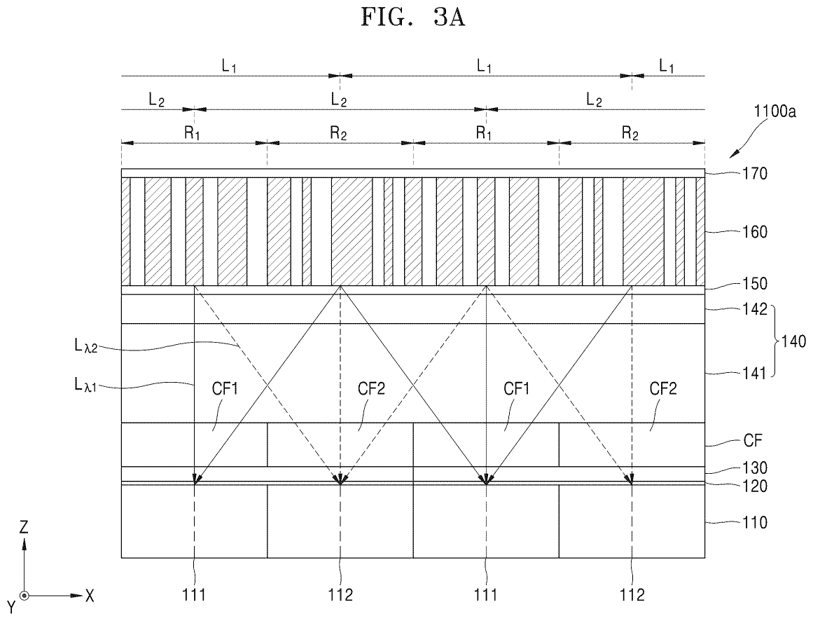

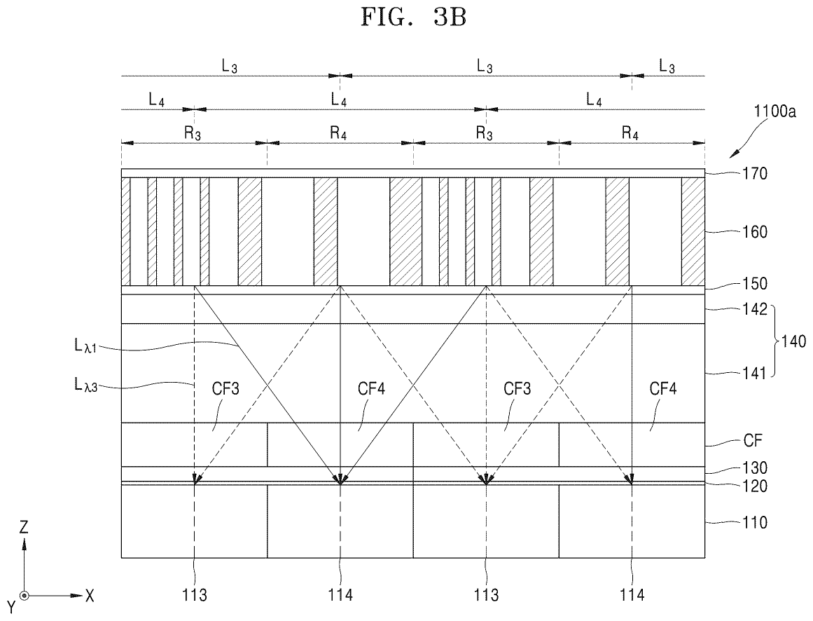

FIGS. 3A and 3B are schematic cross-sectional views showing a configuration of a pixel array 1100a of an image sensor according to an example embodiment. FIG. 3A shows a cross-sectional view taken along line A-A′ of the pixel array 1100a shown in FIG. 2, and FIG. 3B shows a cross-sectional view taken along line B-B′ of the pixel array 1100a shown in FIG. 2.

Referring to FIGS. 3A and 3B, the pixel array 1100a includes a sensor substrate 110, an intermediate layer 120 on the sensor substrate 110, an organic photoelectric conversion layer 130 on the intermediate layer 120, a color filter layer CF on the photoelectric conversion layer 130, a spacer layer 140 on the color filter layer CF, and a nano-photonic lens array 160 on the spacer layer 140. The spacer layer 140 may include a planarization layer 141 and an encapsulation layer 142 on the planarization layer 141. Additionally, the pixel array 1100a may further include an etch stop layer 150 disposed between the spacer layer 140 and the nano-photonic lens array 160. Additionally, the pixel array 1100a may further include an anti-reflection film 170 disposed on a light receiving surface of the nano-photonic lens array 160. The etch stop layer 150 and the anti-reflection film 170 may be omitted.

The sensor substrate 110 may include a plurality of pixels that sense incident light. For example, the sensor substrate 110 may includes a first pixel 111, a second pixel 112, a third pixel 113, and a fourth pixel 114 that generate image signals by converting incident light into electrical signals. The first pixel 111, the second pixel 112, the third pixel 113, and the fourth pixel 114 may form one unit Bayer pattern. For example, the first pixel 111 and the fourth pixel 114 may be green pixels that sense green light, the second pixel 112 may be a blue pixel that senses blue light, and the third pixel 113 may be a blue pixel that senses red light.

The pixel array 1100a may include a plurality of Bayer patterns arranged two-dimensionally. For example, a plurality of first pixels 111 and a plurality of second pixels 112 may be alternately arranged in the first direction (X direction), and a plurality of third pixels 113 and a plurality of fourth pixels 114 may be alternately arranged in the first direction (X direction) in a cross-section at different positions in the second direction perpendicular to the first direction (X direction).

The organic photoelectric conversion layer 130 provided between the sensor substrate 110 and the nano-photonic lens array 160, especially between the sensor substrate 110 and the color filter layer CF may increase carriers by absorbing photons. For example, the organic photoelectric conversion layer 130 may include a material that increase a number of excitons based on multiple exciton generation (MEG) as a singlet fission material that utilizes a triplet excited state among organic materials. In a singlet fission material, one singlet exciton (charge-hole pair) generated by absorbing light is transformed into two triplet exciton pairs, and the generation of multiple excitons refers to a phenomenon in which multiple excitons are generated by absorbing one photon having energy greater than bandgap energy. The organic photoelectric conversion layer 130 includes a singlet fission material, and thus, may generate a large amount of excitons by absorbing incident light, and a signal amplified by the generation of a large amount of excitons may be transmitted to the sensor substrate 110. The organic photoelectric conversion layer 130 may include, for example, polyacene, rylene, rubrene, biradicaloid, or any combination thereof. Polyacene may include anthracene, tetracene, pentacene, or any combination thereof. Rylene may include perylene, terylene, or any combination thereof. Biradicaloid may include benzofuran. The organic photoelectric conversion layer 130 may have a thickness in a range from about 50 nm to about 100 nm. The sum of thicknesses of the intermediate layer 120 and the organic photoelectric conversion layer 130 may be 100 nm or less.

The intermediate layer 120 may further be provided between the sensor substrate 110 and the organic photoelectric conversion layer 130. The intermediate layer 120 may be provided to prevent recombination of charge-electron pairs on a surface of the sensor substrate 110 and to transmit charges generated in the organic photoelectric conversion layer 130 to each of the first through fourth pixels 111, 112, 113, and 114 of the sensor substrate 110. The intermediate layer 120 may include at least one material, for example, silicon oxide (SiOₓ), silicon nitride (SiNₓ), aluminum oxide (Al₂O₃), titanium oxide (TiO₂), hafnium oxide (HfOₓ), hafnium nitride (HfOₓN_{y}), germanium oxide (GeOₓ), and gallium oxide (GaOₓ). The thickness of the intermediate layer 120 may be in a range from about 0.1 nm to about 10 nm.

The color filter layer CF may be provided on the organic photoelectric conversion layer 130, and between the organic photoelectric conversion layer 130 and the spacer layer 140. The color filter layer CF may include a plurality of color filters that transmit light of a specific wavelength and absorb light of other wavelengths. For example, the color filter layer CF may include a first color filter CF1 that transmits light of a first wavelength and absorbs light of wavelengths other than the first wavelength, a second color filter CF2 that transmits light of a second wavelength different from the first wavelength and absorbs light of wavelengths other than the second wavelength, a third color filter CF3 that transmits light of a third wavelength different from the first wavelength and the second wavelength and absorbs light of wavelengths other than the third wavelength, and a fourth color filter CF4 that transmits light of the first wavelength and absorbs light of wavelengths other than the first wavelength.

The spacer layer 140 may be provided between the organic photoelectric conversion layer 130 and the nano-photonic lens array 160, for example, between the color filter layer CF and the nano-photonic lens array 160. The spacer layer 140 may include the planarization layer 141 and the encapsulation layer 142. The planarization layer 141 and the encapsulation layer 142 may be a spacer that provides a distance between the sensor substrate 110 and the nano-photonic lens array 160 so that light passing through the nano-photonic lens array 160 may be focused on the sensor substrate 110. The distance between the sensor substrate 110 and the nano-photonic lens array 160 may be determined by a focal length of the nano-photonic lens array 160. A thickness of the spacer layer 140 may be in a range from about 500 nm to about 1000 nm.

The nano-photonic lens array 160 may be provided on the spacer layer 140. The nano-photonic lens array 160 may be provided between the spacer layer 140 and the anti-reflection layer 170, for example, between the spacer layer 140 and the etch stop layer 150. The nano-photonic lens array 160 may be partitioned in various ways. For example, the nano-photonic lens array 160 may be divided into a first pixel corresponding region R₁, a second pixel corresponding region R₂, a third pixel corresponding regions R₃, and a fourth pixel corresponding region and R₄ corresponding to the first to fourth pixels 111, 112, 113, and 114. The first pixel-corresponding region R₁ may be disposed to face the first pixel 111 on which light L_{λ}_{₁} of the first wavelength included in the incident light Li is concentrated, and the second pixel-corresponding region R₂ may be disposed to face the second pixel 112 on which light L_{λ}_{₂} of the second wavelength included in the incident light Li is concentrated. The third pixel-corresponding region R₃ may be disposed to face the third pixel 113 on which light L_{λ}_{₃} of the third wavelength included in the incident light Li is concentrated, and the fourth pixel-corresponding region R₄ may be disposed to face the fourth pixel 114 on which light L_{λ}_{₁} of the first wavelength included in the incident light Li is concentrated. The first to fourth pixel corresponding regions R₁, R₂, R₃, and R₄ may be two-dimensionally arranged in the first direction (X direction) and the second direction (Y direction) so that the first row in which the first pixel-corresponding region R₁ and the second pixel-corresponding region R₂ are alternately arranged, and a second row in which the third pixel-corresponding region R₃ and the fourth pixel-corresponding region R₄ are alternately arranged. As another example, the nano-photonic lens array 160 may be divided into a first wavelength concentrating region L₁ for concentrating the first wavelength light L_{λ}_{₁} to the first pixel 111, a second wavelength concentrating region L₂ for concentrating the second wavelength light L_{λ}_{₂} to the second pixel 112, a third wavelength concentrating region L₃ for concentrating the third wavelength light L_{λ}_{₃} to the third pixel 113, and a fourth wavelength concentrating region L₄ for concentrating the first wavelength light L_{λ}_{₁} to the fourth pixel 114. Areas of the first to fourth wavelength condensing areas L₁, L₂, L₃, and L₄ may be greater than regions of the corresponding first to fourth pixels 111, 112, 113, and 114, respectively. Some regions of the first to fourth wavelength condensing regions L₁, L₂, L₃, and L₄ may overlap with each other. The first to fourth pixel corresponding regions R₁, R₂, R₃, and R₄ may each include a plurality of nanostructures NP.

The nano-photonic lens array 160 may be configured to form different phase profile for each of the first wavelength light L_{λ}_{₁}, the second wavelength light L_{λ}_{₂}, and the third wavelength light L_{λ}_{₃} included in the incident light Li to focus the first wavelength light L_{λ}_{₁} on the first pixel 111 and the fourth pixel 114, to focus the second wavelength light L_{λ}_{₂} on the first pixel 112, and to focus the third wavelength light L_{λ}_{₃} on the third pixel 113.

The nano-photonic lens array 160 may include a plurality of nanostructures NPs that change the phase of the incident light Li differently depending on the incident position of the incident light Li on the nano-photonic lens array 160. The plurality of nanostructures NPs of the nano-photonic lens array 160 may be configured to form different phase profiles for light of the first to third wavelengths included in the incident light Li, thereby providing color separation between pixels. Because the refractive index of a material varies depending on a wavelength of light that reacts, the nano-photonic lens array 160 may provide different phase profiles from each other with respect to light of the first to third wavelengths L_{λ}_{₁}, L_{λ}_{₂}, and L_{λ}_{₃}. For example, even for the same material, the refractive index may be different depending on the wavelength of light reacting with the material, and the phase delay experienced by light when passing through the material is also different for each wavelength, thus, different phase profiles may be formed for each wavelength. For example, because the refractive index for the first wavelength light L_{λ}_{₁} of the first pixel-corresponding region R₁ and the refractive index for the second wavelength light L_{λ}_{₂} of the first pixel-corresponding region R₂ may be different from each other, and the phase delay experienced by the light L_{λ}_{₁} of the first wavelength that passed through the first pixel-corresponding region R₁ and the phase delay experienced by the light L_{λ}_{₂} of the second wavelength that passed through the first pixel-corresponding region R₁ may be different from each other, when the nano-photonic lens array 160 is provided considering these characteristics of light, different phase profiles may be provided for the first to third wavelengths of light L_{λ}_{₁}, L_{λ}_{₂}, and L_{λ}_{₃}.

Each of the first to fourth pixel corresponding regions R₁, R₂, R₃, and R₄ may include a plurality of nanostructures NPs capable of color separation and light concentration, and shapes, size (width, height), spacing, arrangement form, etc. of the plurality of nanostructures NPs may be determined so that the light immediately after passing through each of the first to fourth pixel corresponding regions R₁, R₂, R₃, and R₄ has a predetermined phase profile depending on a wavelength. For example, light at a lower surface of each of the first to fourth pixel corresponding regions R₁, R₂, R₃, and R₄ may have a predetermined phase profile depending on a wavelength. According to the phase profile, a travel direction and focal distance of the light passing through the first to fourth pixel corresponding regions R₁, R₂, R₃, and R₄, respectively, may be determined.

A nanostructure NP may be a nanopillar having a cross-sectional diameter (or width) of a sub-wavelength dimension. Here, the sub-wavelength may be a wavelength less than a wavelength band of light being focused. When the incident light is visible light, a cross-sectional diameter of the nanostructure NP in the horizontal direction (X or Y direction) may have a dimension, for example, less than 400 nm, 300 nm, or 200 nm. A height of the nanostructure NP in a vertical direction (Z direction) may be in a range from about 500 nm to about 1500 nm, and the height may be greater than the diameter of the cross-section.

The nanostructures NPs may include a material that has a relatively high refractive index compared to surrounding materials and a relatively low absorption rate in the visible light band. For example, the nanostructure NP may include c-Si, p-Si, a-Si and a Group III-V compound semiconductor (gallium phosphide (GaP), gallium nitride (GaN), gallium arsenide (GaAs), etc.), silicon carbide (SiC), titanium oxide (TiO₂), silicon nitride (SiN₃), zinc sulfide (ZnS), zinc selenide (ZnSe), silicon nitride (Si₃N₄), and/or any combination thereof. A region around the nanostructure NP may be filled with a dielectric material that has a lower refractive index than the nanostructure NP and has a relatively low absorption rate in the visible light band. The dielectric material may be provided on a side surface of the nanostructure NP. For example, the region around the nanostructure NP may be filled with SiO₂, siloxane-based spin on glass (SOG), air, etc. The refractive index of the nanostructure NP may be about 2.0 or more with respect to light with a wavelength of about 630 nm, and the refractive index of a surrounding material may be about 1.0 or more and less than 2.0 with respect to light with a wavelength of about 630 nm. Also, the difference between the refractive index of the nanostructure NP and the refractive index of the surrounding material may be about 0.5 or more. The nanostructures NPs that have a difference in refractive index from surrounding materials may change a phase of light passing through the nanostructures NPs. This is due to phase delay caused by a shape dimension of a sub-wavelength shape of the nanostructure NP, and the degree of phase delay is determined by the detailed shape dimension, arrangement type, etc. of the nanostructure NP.

Widths and arrangements of the plurality of nanostructures NP provided in each of the first to fourth pixel corresponding regions R₁, R₂, R₃, and R₄ may vary depending on the wavelength band sensed by a pixel corresponding to each of the first to fourth pixel corresponding regions R₁, R₂, R₃, and R₄. For example, the width and arrangement of the plurality of nanostructures NP provided in the first pixel-corresponding region R₁ may differ from the width and arrangement of the plurality of nanostructures NP provided in each of the second to fourth pixel corresponding regions R₂, R₃, and R₄. For convenience, the first pixel-corresponding region R₁ has been described as an example, and the same applies to the second to fourth pixel corresponding regions R₂, R₃, and R₄.

The light passing through the nano-photonic lens array 160 may be provided to have different phase profiles for each color by adjusting the size (width or height), shape, and arrangement of the plurality of nanostructures NPs of the nano-photonic lens array 160. The nano-photonic lens array 160 may collect light by separating incident light by color, and the color balance and light use efficiency of the image sensor 1000 may be improved.

The etch stop layer 150 may be provided between the spacer layer 140 and the nano-photonic lens array 160. The etch stop layer 150 may protect the layers below the nano-photonic lens array 160 during an etching process to form the nano-photonic lens array 160. The etch stop layer 150 may not be easy etch compared to the encapsulation layer 142 below the etch stop layer 150, and may include a material having a high refractive index with respect to visible light. For example, the etch stop layer 150 may include a material, such as aluminum oxide (Al₂O₃) or hafnium oxide (HfO₂). A thickness of the etch stop layer 150 may be in a range from about 5 nm to about 50 nm.

Also, the anti-reflection film 170 disposed on the light incident surface of the nano-photonic lens array 160 may improve the light utilization efficiency of the image sensor 1000 by reducing light reflected from the upper surface of the nano-photonic lens array 160 among the incident light. The anti-reflection film 170 may include a material that has a refractive index different from a refractive index of the material of the nanostructure NP of the nano-photonic lens array 160. For example, an average refractive index of the anti-reflection film 170 may be greater than the refractive index of air and less than an average refractive index of the nano-photonic lens array 160. For example, the anti-reflection film 170 may be a single layer including any one of SiO₂, Si₃N₄, and Al₂O₃. The anti-reflection film 170 may be formed to have a thickness in a range from about 80 nm to about 120 nm. According to another example embodiment, the anti-reflection film 170 may have a multilayer structure formed by alternately stacking different dielectric materials. For example, the anti-reflection film 170 may be formed by alternately stacking two or three materials among SiO₂, Si₃N₄, and Al₂O₃. According to still another example embodiment, the anti-reflection film 170 may include various patterns patterned to prevent reflection of incident light.

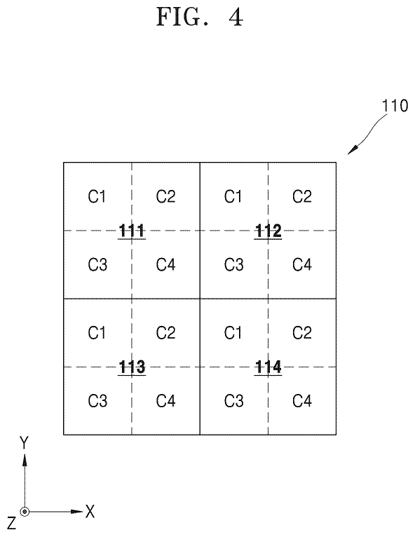

FIG. 4 is a schematic plan view showing a configuration of the sensor substrate 110 of the pixel array shown in FIGS. 3A and 3B. Referring to FIG. 4, the sensor substrate 110 may include a plurality of pixels that sense incident light. For example, the sensor substrate 110 includes a first pixel 111, a second pixel 112, a third pixel 113, and a fourth pixel 114 that generate image signals by converting incident light into electrical signals. The first pixel 111, the second pixel 112, the third pixel 113, and the fourth pixel 114 may form one unit Bayer pattern. For example, the first pixel 111 and the fourth pixel 114 are green pixels that sense green light, the second pixel 112 is a blue pixel that senses blue light, and the third pixel 113 is a red pixel that senses red light.

Although only one unit Bayer pattern including four pixels is shown in FIG. 3 as an example, the pixel array 1100 may include a plurality of Bayer patterns two-dimensionally arranged. For example, a plurality of first pixels 111 and a plurality of second pixels 112 are alternately arranged in the first direction (X direction), and a plurality of third pixels 113 and a plurality of fourth pixels 114 may be alternately arranged in the first direction (X direction) in a cross section at different position in the second direction perpendicular to the first direction (X direction).

Each of the first to fourth pixels 111, 112, 113, and 114 may include a plurality of light sensing cells that independently detect incident light. For example, each of the first to fourth pixels 111, 112, 113, and 114 may include first to fourth photo-sensing cells c1, c2, c3, and c4. The first to fourth photo-sensing cells c1, c2, c3, and c4 may be two-dimensionally arranged in the first direction (X direction) and the second direction (Y direction). For example, the first to fourth photo-sensing cells c1, c2, c3, and c4 may be arranged in a 2×2 array in each of the first to fourth pixels 111, 112, 113, and 114.

In FIG. 4, it is depicted that each of the first to fourth pixels 111, 112, 113, and 114 includes four photo-sensing cells, but four or more independent photo-sensing cells may be clustered and two dimensionally arranged. For example, each of the first to fourth pixels 111, 112, 113, and 114 may include a plurality of independent photo-sensing cells arranged in a 3×3 array or a 4×4 array. Hereinafter, for convenience, a case when each of the first to fourth pixels 111, 112, 113, and 114 includes photo-sensing cells arranged in a 2×2 array will be described.

According to example embodiments, an autofocus signal may be obtained from a difference between output signals of adjacent photo-sensing cells. For example, an autofocus signal in the first direction (X direction) may be generated from a difference between an output signal of the first photo-sensing cell c1 and an output signal of the second photo-sensing cell c2, a difference between an output signal of the third photo-sensing cell c3 and an output signal of the fourth photo-sensing cell c4, or a difference between the sum of the output signals of the first photo-sensing cell c1 and the third photo-sensing cell c3 and the sum of the output signals of the second photo-sensing cell c2 and the fourth photo-sensing cell c4. Also, an autofocus signal in the second direction (Y direction) may be generated from a difference between the output signal of the first photo-sensing cell c1 and the output signal of the third photo-sensing cell c3, a difference between the output signal of the second photo-sensing cell c2 and the output signal of the fourth photo-sensing cell c4, or a difference between the sum of the output signals of the first photo-sensing cell c1 and the second photo-sensing cell c2 and the sum of the output signals of the third photo-sensing cell c3 and the fourth photo-sensing cell c4.

A general image signal may be obtained by adding the output signals of the first to fourth photo-sensing cells c1, c2, c3, and c4. For example, a first green image signal may be generated by combining the output signals of the first to fourth photo-sensing cells c1, c2, c3, and c4 of the first pixel 111, a blue image signal may be generated by combining the output signals of the first to fourth photo-sensing cells c1, c2, c3, and c4 of the second pixel 112, a red image signal may be generated by combining the output signals of the first to fourth photo-sensing cells c1, c2, c3, and c4 of the third pixel 113, and a second green image signal may be generated by combining the output signals of the first to fourth photo-sensing cells c1, c2, c3, and c4 of the first pixel 114.

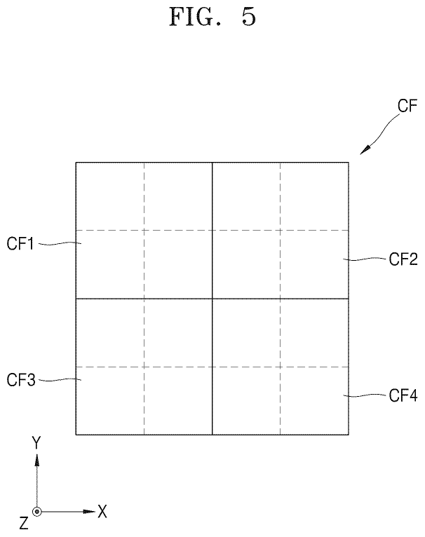

FIG. 5 is a schematic plan view showing a configuration of a color filter layer CF shown in FIGS. 3A and 3B.

Referring to FIG. 5, the color filter layer CF may include a plurality of color filters that transmit light of a specific wavelength and absorb light of other wavelengths. For example, the color filter layer CF may include a first color filter CF1 that transmits light of a first wavelength and absorbs light of wavelengths other than the first wavelength, a second color filter CF2 that transmits light of a second wavelength different from the first wavelength and absorbs light of wavelengths other than the second wavelength, a third color filter CF3 that transmits light of a third wavelength different from the first and second wavelengths and absorbs light of wavelengths other than the third wavelength, and a fourth color filter CF4 that transmits light of the first wavelength and absorbs light of wavelengths other than the first wavelength. In FIG. 5, although only one unit Bayer pattern is shown as an example, a plurality of first color filters CF1 and a plurality of second color filters CF2 may be alternately arranged in the first direction (X direction), and a plurality of third color filters CF3 and a plurality of fourth color filters CF4 may be alternately arranged in the first direction (X direction) in a cross-section at different positions in the second direction (Y direction) perpendicular to the first direction (X direction).

The first color filter CF1 may be arranged to face the first pixel 111 in a third (vertical) direction (Z direction), the second color filter CF2 may be arranged to face the second pixel 112 in the third direction (Z direction), the third color filter CF3 may be arranged to face the third pixel 113 in the third direction (Z direction), and the fourth color filter CF4 may be arranged to face the fourth pixel 114 in the third direction (Z direction). Accordingly, the first pixel 111 and the fourth pixel 114 may detect light of the first wavelength that has passed through the corresponding first color filter CF1 and fourth color filter CF4, respectively. Also, the second pixel 112 may detect light of the second wavelength that has passed through the corresponding second color filter CF2. The third pixel 113 may detect light of the third wavelength that has passed through the corresponding third color filter CF3. For example, the first color filter CF1 and the fourth color filter CF4 may be green color filters that transmit green light, the second color filter CF2 may be a blue color filter that transmits blue light, and the third color filter CF3 may be a red color filter that transmits red light.

The dashed line shown in FIG. 5 represents separation films between the photo-sensing cells of the first to fourth pixels 111, 112, 113, and 114. As shown in FIG. 5, the first to fourth color filters CF1, CF2, CF3, and CF4 may be arranged to face all and each of the photo-sensing cells included in the corresponding first to fourth pixels 111, 112, 113, and 114 in the third direction (Z direction). For example, the first color filter CF1 may cover and face all the photo-sensing cells in the first pixel 111, the second color filter CF2 may cover and face all the photo-sensing cells in the second pixel 112, the third color filter CF3 may cover and face all the photo-sensing cells in the third pixel 113, and the fourth color filter CF4 may cover and face all the photo-sensing cells in the fourth pixel 114.

The first to fourth color filters CF1, CF2, CF3, and CF4 of the color filter layer CF may include, for example, an organic polymer material. For example, the first to fourth color filters CF1, CF2, CF3, and CF4 may include a colorant, binder resin, and polymer photoresist. The first and fourth color filters CF1 and CF4 may be organic color filters including a green organic dye or a green organic pigment as a colorant, the second color filter CF2 may be an organic color filter including a blue organic dye or a blue organic pigment as a colorant, and the third color filter CF3 may be an organic color filter including a red organic dye or a red organic pigment as a colorant. In FIGS. 3A, 3B, and 5 for convenience, the color filter layer CF may further include a black matrix disposed at a boundary between the first to fourth color filters CF1, CF2, CF3, and CF4. The black matrix may include, for example, carbon black.

In FIGS. 3A and 3B, for convenience, the color filter layer CF is shown as having a flat upper surface. However, upper surfaces of the first to fourth color filters CF1, CF2, CF3, and CF4 may not be flat. Also, thicknesses of the first to fourth color filters CF1, CF2, CF3, and CF4 and the black matrix therebetween may not be the same. The planarization layer 141 disposed on the color filter layer CF may provide a flat surface for forming the nano-photonic lens array 160 on the planarization layer 141. The planarization layer 141 may include an organic polymer material that is suitable for layering on the color filter layer CF including an organic material and is easier to form a flat surface. The organic polymer material for forming the planarization layer 141 may have properties for visible light. For example, the planarization layer 141 may include at least one organic polymer material selected from epoxy resin, polyimide, polycarbonate, polyacrylate, and polymethyl methacrylate (PMMA). The planarization layer 141 may be formed on the color filter layer CF using, for example, a spin coating method, and may have a flat upper surface through heat treatment.

The encapsulation layer 142 may further be disposed on the planarization layer 141. The encapsulation layer 142 may serve as a protective layer that prevents the planarization layer 141 including an organic polymer material from being damaged during the process of forming the nano-photonic lens array 160 on the planarization layer 141. In addition, the encapsulation layer 142 may serve as an anti-diffusion layer that prevents a metal component of the color filter layer CF from passing through the planarization layer 141 and being exposed to the outside due to relatively high temperature in the process of forming the nano-photonic lens array 160. To this end, the encapsulation layer 142 may include an inorganic material. The inorganic material of the encapsulation layer 142 may be formed at a temperature less than the process temperature for forming the nano-photonic lens array 160 and may include a transparent material for visible light. For example, the encapsulation layer 142 may include at least one inorganic material selected from SiO₂, SiN, and silicon oxynitride (SiON).

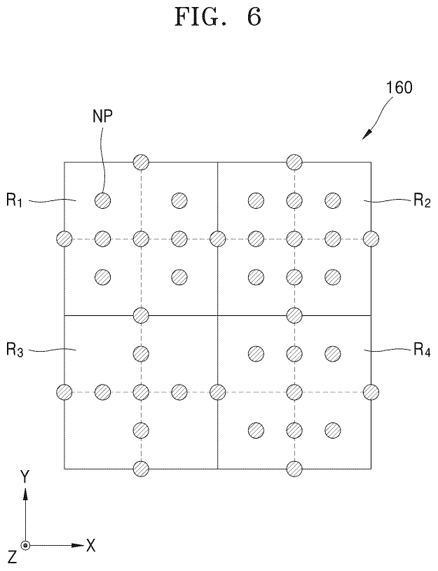

FIG. 6 is a plan view illustrating a configuration of the nano-photonic lens array 160 shown in FIGS. 3A and 3B.

Referring to FIG. 6, the nano-photonic lens array 160 may include a first lens 161 corresponding to the first pixel 111, a second lens 162 corresponding to the second pixel 112, a third lens 163 corresponding to the third pixel 113, and a fourth lens 164 corresponding to the fourth pixel 114. For example, the first lens 161 may be arranged to face the first pixel 111 in the third direction (Z direction), the second lens 162 may be arranged to face the second pixel 112 in the third direction (Z direction), the third lens 163 may be arranged to face the third pixel 113 in the third direction (Z direction), and the fourth lens 164 may be arranged to face the fourth pixel 114 in the third direction (Z direction). Although only one unit Bayer pattern is shown as an example in FIG. 6, a plurality of first lenses 161 and a plurality of second lenses 162 may be alternately arranged in the first direction (X direction), and a plurality of third lenses 163 and a plurality of fourth lenses 164 may be alternately arranged in the first direction (X direction) in a cross section at different positions in the second direction (Y direction) perpendicular to the first direction (X direction).

The nano-photonic lens array 160 may include a plurality of nanostructures NPs arranged to collect incident light on the first to fourth pixels 111, 112, 113, and 114, respectively. The plurality of nanostructures NPs may be arranged to change a phase of transmitted light that passes through the nano-photonic lens array 160 differently depending on the position on the nano-photonic lens array 160. Phase profiles of transmitted light implemented by the nano-photonic lens array 160 may be determined according to a width (or diameter) and height of each nanostructure NP and an arrangement period (or pitch) and arrangement form of the plurality of nanostructures NP. Also, the behavior of light transmitted through the nano-photonic lens array 160 may be determined according to the phase profile of the transmitted light. For example, a plurality of nanostructures NPs may be arranged to form a phase profile that allows light passing through the nano-photonic lens array 160 to be collected.

The nano-photonic lens array 160 including the plurality of nanostructures NPs described above may separate incident light by wavelength and collect the incident light, and the separated and collected light by wavelength may be transmitted to the organic photoelectric conversion layer 130 through the color filter layer CF. In addition, because a signal amplified by the increase in the number of excitons through an multi exciton generation (MEG) effect by the organic photoelectric conversion layer 130 is transmitted to a photodiode, the light utilization efficiency of the image sensor 1000 may be improved. Also, the nanostructure NP of the nano-photonic lens array 160 may be provided to correspond to a color balance, and the color balance may improve the light utilization efficiency of the image sensor 1000 with different color balance.

According to example embodiments, the structure, arrangement, and size of the nanostructures NPs of the nano-photonic lens array 160 may be appropriately selected according to the color balance of the image sensor. The quantum efficiency spectrum for each color of the image sensor 1000 may be changed by changing, for example, a structure, size (width, height), and arrangement of the nanostructure NP of the nano-photonic lens array 160.

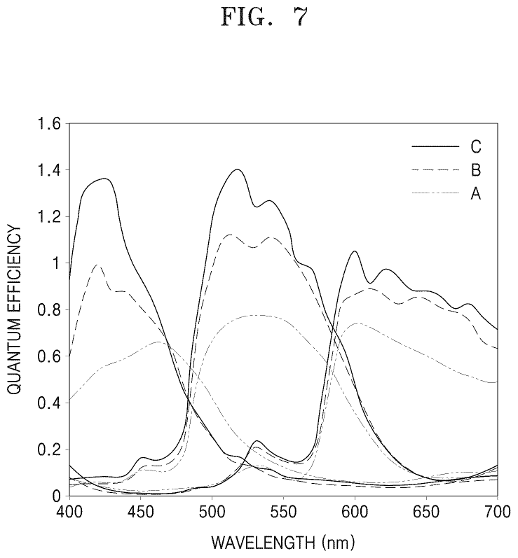

FIG. 7 illustrates graphs showing the efficiency of an image sensor to which the pixel array of FIGS. 3A and 3B is applied. In FIG. 7, A represents the efficiency of an image sensor according to a related example including only a color filter, B represents the efficiency of an image sensor to which a nano-photonic lens array is applied, and C represents an image sensor to which a nano-photonic lens array and an organic photoelectric conversion layer are applied.

Referring to FIG. 7, in the case when the nano-photonic lens array is applied to an image sensor, it may be seen that light utilization efficiency (e.g., quantum efficiency (QE) that represents a ratio of absorbed photons and converted electrons) is generally improved than that of a conventional image sensor. In addition, when a nano-photonic lens array and an organic photoelectric conversion layer are applied together to an image sensor, it may be seen that the light utilization efficiency is additionally improved while maintaining a similar crosstalk level.

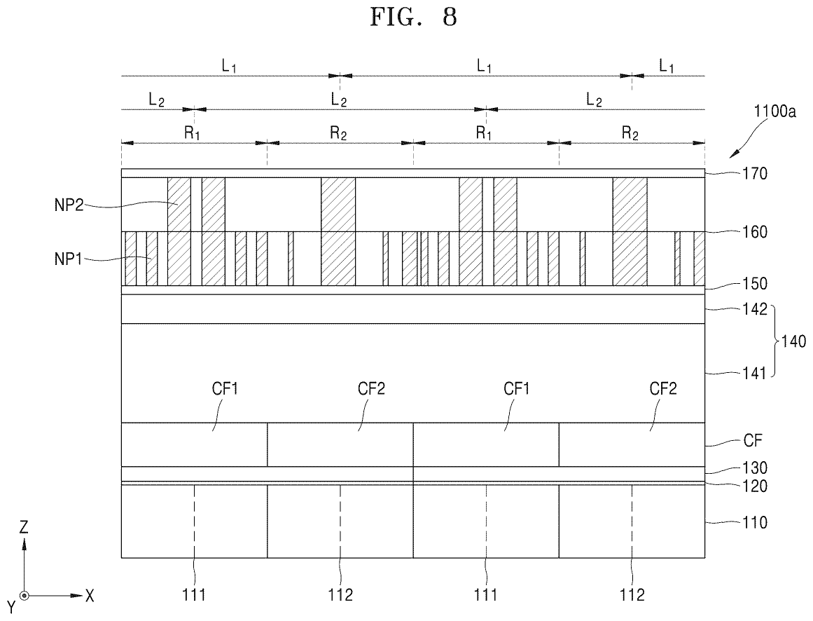

FIG. 8 is a schematic cross-sectional view showing a configuration of a pixel array of an image sensor according to another example embodiment. For convenience, only the first and second pixels 111 and 112 and the corresponding components are shown in FIG. 8, but the descriptions below may also be applied to the third and fourth pixels and the corresponding components. To avoid duplicative descriptions, the differences from FIG. 3A will be described.

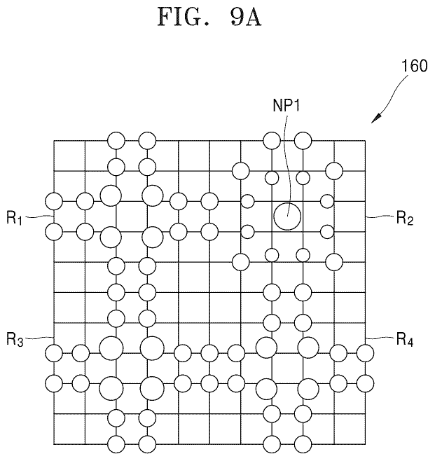

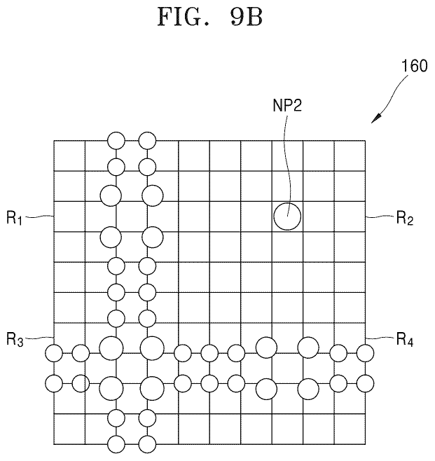

Referring to FIG. 8, the nano-photonic lens array 160 of the pixel array 1100a may have a multi-layer structure. For example, the nano-photonic lens array 160 may include a plurality of first nanostructures NP1 and a plurality of second nanostructures NP2 provided on the first nanostructures NP1. The plurality of first nanostructures NP1 and the plurality of second nanostructures NP2 may be arranged in a multi-layer structure. The arrangement of the plurality of first nanostructures NP1 and the arrangement of the plurality of second nanostructures NP2 in the nano-photonic lens array 160 may be the same. According to another example embodiment, the arrangement of the plurality of first nanostructures NP1 and the plurality of second nanostructures NP2 in the nano optical lens array 160 may be different from each other. For example, as shown in FIG. 9, to improve the efficiency of the nano-photonic lens array 160, the arrangement of the plurality of first nanostructures NP1 and the plurality of second nanostructures NP2 may be different.

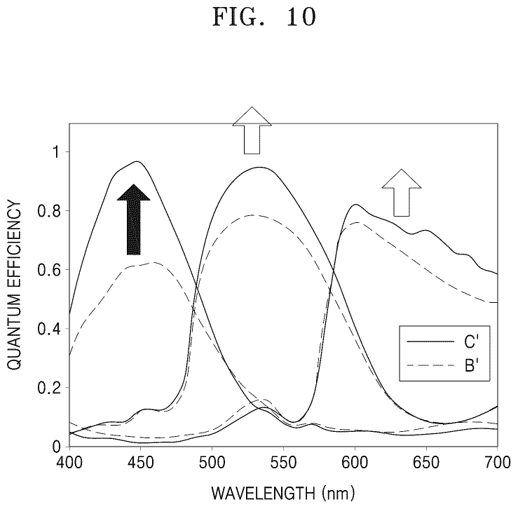

FIGS. 9A and 9B are plan views showing an example arrangement of nanostructures of the nano-photonic lens array of FIG. 8 in more detail, and FIG. 10 is a graph showing the efficiency of the image sensor to which the arrangement of the nanostructures of the nano-photonic lens array of FIGS. 9A and 9B and a resulting organic photoelectric conversion layer are applied.

To improve the efficiency of using blue light, the plurality of first nanostructures NP1 of the nano-photonic lens array 160 may be arranged as shown in FIG. 9A, and the plurality of second nanostructures NP2 of the nano-photonic lens array 160 may be arranged as shown in FIG. 9B.

Referring to FIGS. 9A and 9B, in the first, second, and fourth pixel-corresponding regions R₁, R₂, and R₄, the plurality of first nanostructures NP1 and the plurality of second nanostructures NP2 may be arranged in a different manner. Also, in the third pixel-corresponding region R₃, the plurality of first nanostructures NP1 may be arranged in the same manner as the plurality of second nanostructures NP2. For example, the first pixel-corresponding region R₁ and the fourth pixel-corresponding region R₄, may not include any second nanostructure NP2 at an edge portion (peripheral portion) close to and adjacent to the second pixel-corresponding region R₂, but may include only the first nanostructure NP1. Also, the second nanostructure NP2 may be provided only at the center of the second pixel-corresponding region R₂.

Also, when the plurality of nanostructures NP1 and NP2 of the nano-photonic lens array 160 are arranged to improve the utilization efficiency of blue light as shown in FIGS. 9A and 9B, a material and thickness that improve the utilization efficiency of red light and green light may be applied to the organic photoelectric conversion layer 130.

FIG. 10 illustrates graphs showing the efficiency of an image sensor to which the nano-photonic lens array of FIGS. 9A and 9B is applied. In FIG. 10, B′ represents the efficiency of an image sensor according to a related example including only a color filter, C′ represents an image sensor to which a nano-photonic lens array and the organic photoelectric conversion layer of FIGS. 9A and 9B is applied.

Referring to FIG. 10, graph C′ illustrates that the light utilization efficiency of the image sensor according to example embodiments is improved in a blue wavelength band (black arrow) by applying the arrangement of the plurality of nanostructures NP1 and NP2 of the nano-photonic lens array 160 of FIGS. 9A and 9B compared to graph B′ illustrating the light utilization efficiency of an image sensor according to the related example including only a color filter. In addition, it may be seen that the light utilization efficiency of an image sensor according to the example embodiments as illustrated in graph C′ is improved in red and green wavelength bands of the image sensor (white arrows) by applying the organic photoelectric conversion layer 130, which improves the utilization efficiency of red light and green light, when compared to the light utilization efficiency of the image sensor according to the related example as illustrated in graph B′.

The light utilization efficiency of the image sensor to which the above-described nano-photonic lens array 160 and the organic photoelectric conversion layer 130 are applied as illustrated in graph C′ may have an overall improved spectrum compared to the light utilization efficiency of an image sensor of the related art as illustrated in graph B′ as shown in FIG. 10.

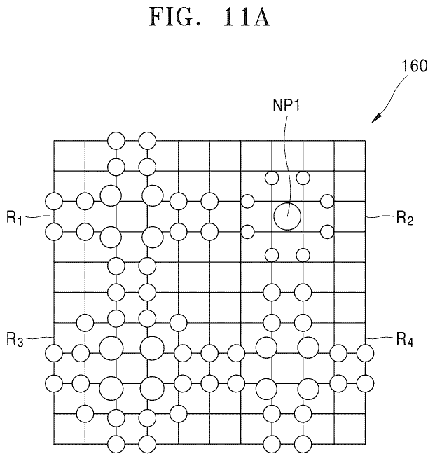

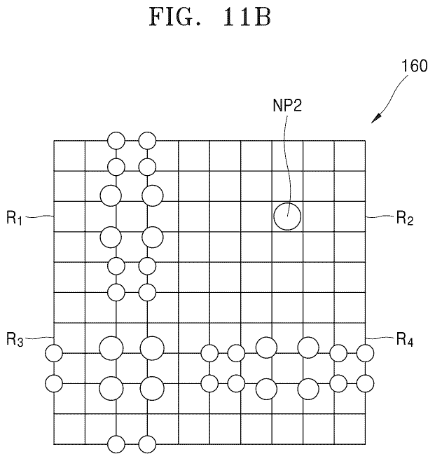

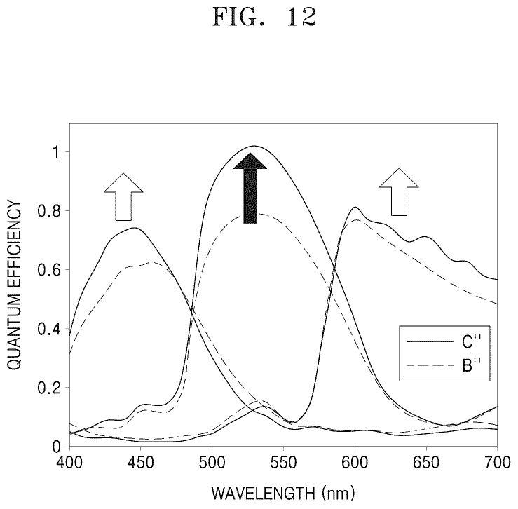

FIGS. 11A and 11B are plan views showing in more detail another example arrangement of nanostructures of the nano-photonic lens array 160 of FIG. 8, and FIG. 12 is a graph showing the efficiency of the image sensor to which the arrangement of nanostructures of the nano-photonic lens array of FIGS. 11A and 11B and a resulting organic photoelectric conversion layer are applied.

To improve the utilization efficiency of green light, the first nanostructure NP1 and the second nanostructure NP2 of the nano-photonic lens array 160 may be arranged as shown in FIGS. 11A and 11B. In FIG. 11B, it may be seen that less number of the second nanostructures NP2 are arranged in the third pixel-corresponding region R₃ compared to FIG. 9B.

In addition, when the nanostructures NP1 and NP2 of the nano-photonic lens array 160 are arranged to improve the utilization efficiency of green light as shown in FIGS. 11A and 11B, a material and thickness that improve the utilization efficiency of blue light and red light may be applied to the organic photoelectric conversion layer 130.

FIG. 12 illustrates graphs showing the efficiency of an image sensor to which the nano-photonic lens array of FIGS. 11A and 11B is applied. In FIG. 10, B″ represents the efficiency of an image sensor according to a related example including only a color filter, C″ represents an image sensor to which a nano-photonic lens array and the organic photoelectric conversion layer of FIGS. 11A and 11B is applied.

Referring to FIG. 12, it may be seen that the light utilization efficiency of the image sensor according to example embodiments as illustrated in graph C″ is improved in a green wavelength band (black arrow) by applying the arrangement of the plurality of nanostructures NP1 and NP2 of the nano-photonic lens array 160 of FIGS. 11A and 11B compared to the light utilization efficiency of an image sensor of the related art as illustrated in graph B″. In addition, it may be seen that the light utilization efficiency of an image sensor according to the example embodiments is improved in blue and red wavelength bands of the image sensor (white arrows) by applying the organic photoelectric conversion layer 130 as illustrated in graph C″, which improves the utilization efficiency of blue light and red light, when compared to the light utilization efficiency of the image sensor of the related art as illustrated in graph B″.

The light utilization efficiency of the image sensor to which the above-described nano-photonic lens array 160 and the organic photoelectric conversion layer 130 are applied as illustrated in graph C″ may have an overall improved spectrum compared to the light utilization efficiency of an existing image sensor as illustrated in graph B″ as shown in FIG. 12.

When the nanostructures NP1 and NP2 of the nano-photonic lens array 160 are arranged to improve the utilization efficiency of red light, a material and thickness that improves the utilization efficiency of blue light and green light may be applied to the organic photoelectric conversion layer 130. The material of the organic photoelectric conversion layer 130, which improves the utilization efficiency of blue light and green light, may be, for example, tetracene. Also, the thickness of the organic photoelectric conversion layer 130, which improves the utilization efficiency of blue light and green light, may be, for example, in a range from about 20 nm to about 40 nm. More specifically, the thickness of the organic photoelectric conversion layer 130 that improves the utilization efficiency of blue light and green light may be approximately 30 nm.

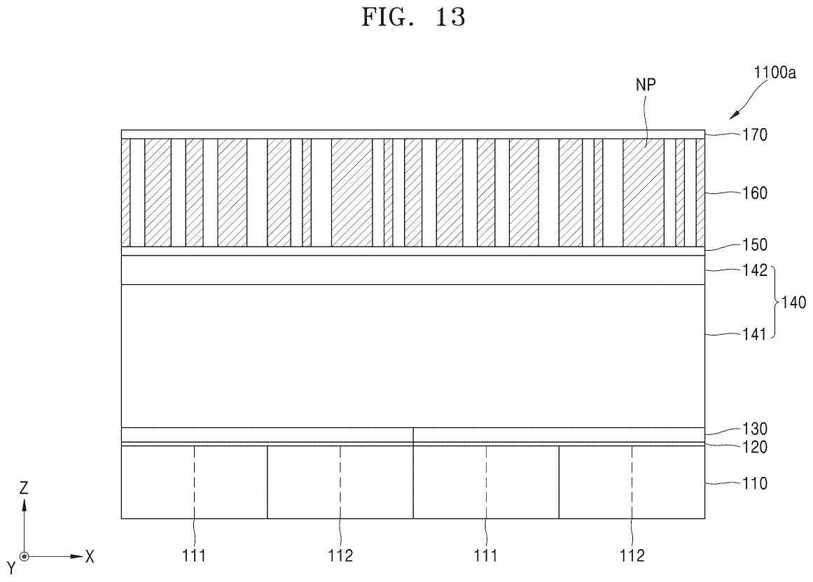

FIGS. 13 to 15 are schematic cross-sectional views showing a configuration of a pixel array of an image sensor according to various example embodiments. In FIGS. 13 to 15, for convenience, only the first and second pixels 111 and 112 and the corresponding components are shown, but the descriptions below may also be applied to the third and fourth pixels and the corresponding components. To avoid duplicative descriptions, differences from FIG. 3A will be mainly described.

Referring to FIG. 13, the pixel array 1100a may not include the color filter layer CF. According to another example embodiment, the pixel array 1100a may include an inorganic color filter including a nano-pattern instead of an organic color filter including an organic material. When the pixel array 1100a includes an inorganic color filter, the encapsulation layer 142 may be omitted.

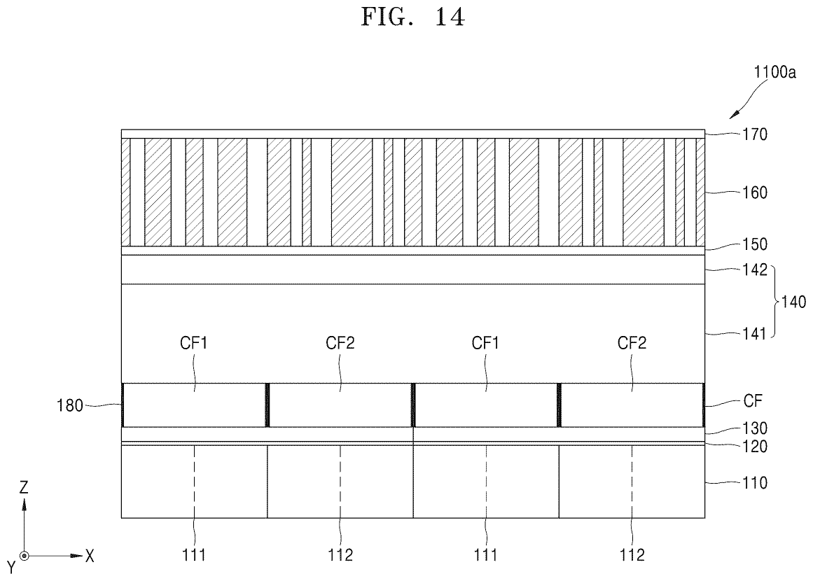

Also, referring to FIG. 14, the pixel array 1100a may include barrier walls 180 that separate each of the first to second color filters CF1 and CF2 and the third to fourth color filters. The barrier walls 180 may extend in the first direction (X direction) and the second direction (Y direction) to separate the first to second color filters CF1 and CF2 and the third to fourth color filters, respectively. The barrier walls 180 may extend from upper parts to lower parts of the first to second color filters CF1 and CF2 and the third to fourth color filters in the third direction (Z direction) to separate the first to second color filters CF1 and CF2 and the third to fourth color filters, respectively. The color filter layer CF of the pixel array 1100a may be divided into four by the barrier walls 180.

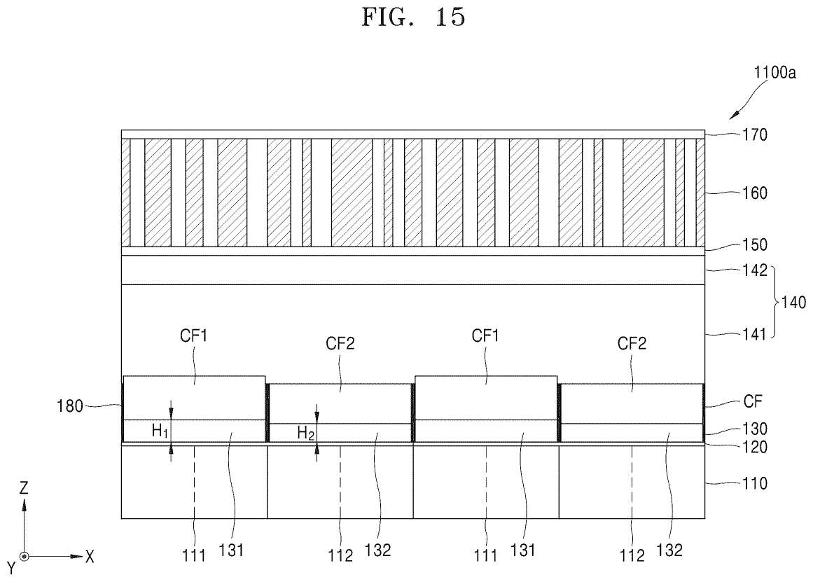

Also, referring to FIG. 15, in the pixel array 1100a, barrier walls 180 that separates the first and second color filters CF1 and CF2 and the third and fourth color filters may extend in the third direction (Z direction) from the upper parts of the first to second color filters CF1 and CF2 and the third to fourth color filters to a certain portion at a lower part of the organic photoelectric conversion layer 130. The color filter layer CF and the organic photoelectric conversion layer 130 of the pixel array 1100a may each be divided into four by the barrier walls 180. The organic photoelectric conversion layer 130 may be divided into a plurality of organic photoelectric conversion elements 131 and 132 by the barrier walls 180. Although only the first to second organic photoelectric conversion elements 131 and 132 are shown in FIG. 15 for convenience, third to fourth organic photoelectric conversion elements may be provided on the third and fourth pixels, respectively. The first and second organic photoelectric conversion elements 131 and 132 and the third and fourth organic photoelectric conversion elements may each have different thicknesses depending on the color of the color filter layer CF provided thereon. For example, a thickness H1 of the first organic photoelectric conversion element 131 corresponding to the first color filter CF1 may be different from a thickness H2 of the second organic photoelectric conversion element 132 corresponding to the second color filter CF2 in the third direction (Z direction). A thickness H3 of the third organic photoelectric conversion element corresponding to the third color filter CF3 may differ from the thicknesses H1 and H2. A thickness H4 of the fourth organic photoelectric conversion element corresponding to the fourth color filter CF4 (e.g., green color filter) may differ from the thicknesses H1, H2, and H3 corresponding to the first, second, and third color filters CF1, CF2, and CF3 (e.g., green, blue, and red color filters) or alternatively, may differ from the thicknesses H2 and H3 corresponding to the second and third color filters CF2 and CF3 (e.g., blue and red color filters) but be the same as the thickness Hi corresponding to the first color filter CF1 (e.g., green color filter).

Light utilization efficiency may further be improved by providing the first to fourth organic photoelectric conversion elements 131 and 132 with different thicknesses for each color of the corresponding color filter.

The image sensor 1000 described above may have improved light utilization efficiency, and a color balance of the image sensor 1000 may be adjusted. As light utilization efficiency improves, it may be possible to reduce a size of one pixel of the image sensor 1000 or a size of independent light sensing cells within the pixel may be reduced. Therefore, an image sensor 1000 with higher resolution may be provided. The image sensor 1000 according to embodiments may form a camera module with module lenses of various performances and may be used in various electronic apparatuses.

The image sensor 1000 described above may be employed in various high-performance optical apparatuses or high-performance electronic apparatuses. The electronic apparatuses may include, for example, various portable devices, such as smart phones, personal digital assistants (PDAs), laptops, and personal computers PCs, home appliances, security cameras, medical cameras, automobiles, and the Internet of Things (IoT) devices, other mobile or non-mobile computing devices, but embodiments are not limited thereto.

In addition to the image sensor 1000, the electronic apparatus may further include a processor that controls the image sensor 1000, for example, an application processor (AP), may control multiple hardware or software constituent elements by driving an operating system or application program through a processor, and may perform various data processing and calculations. The processors may further include a graphics processing unit (GPU) and/or an image signal processor. When the processor includes an image signal processor, an image (or video) acquired by the image sensor 1000 may be stored and/or output using the processor.

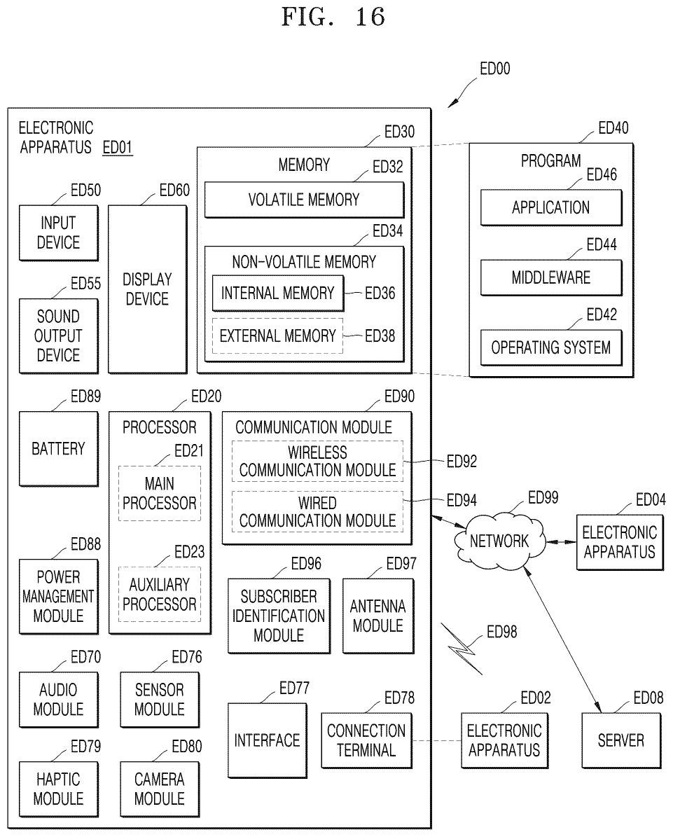

FIG. 16 is a block diagram illustrating an example of an electronic apparatus ED01 including the image sensor 1000. Referring to FIG. 16, in a network environment ED00, an electronic apparatus ED01 may communicate with another electronic apparatus ED02 through a first network ED98 (a short-range wireless communication network, etc.), or may communicate with another electronic apparatus ED04 and/or a server ED08 through a second network ED99 (a long-distance wireless communication network). The electronic apparatus ED01 may communicate with an electronic apparatus ED04 through a server ED08. The electronic apparatus ED01 may include a processor ED20, a memory ED30, an input device ED50, an audio output device ED55, a display device ED60, an audio module ED70, a sensor module ED76, an interface ED77, a haptic module ED79, a camera module ED80, a power management module ED88, a battery ED89, a communication module ED90, a subscriber identity module ED96, and/or an antenna module ED97. In the electronic apparatus ED01, some of these components (such as the display device ED60) may be omitted or other components may be added. Some of these components can be implemented as one integrated circuit. For example, a sensor module ED76 (fingerprint sensor, iris sensor, illumination sensor, etc.) may be implemented in a form embedded in the display device ED60 (a display, etc.).

The processor ED20 may execute software (such as a program ED40) to control one or a plurality of other components (hardware, software components, etc.) of the electronic apparatus ED01 connected to the processor ED20 and may perform various data processing or operations. As part of data processing or computation, the processor ED20 may load commands and/or data received from other components (the sensor module ED76, the communication module ED90, etc.) into volatile memory ED32 and may process commands and/or data stored in the volatile memory ED32, and store resulting data in a non-volatile memory ED34. The processor ED20 may include a main processor 2221 (a central processing unit, an application processor, etc.) and an auxiliary processor ED23 (a graphics processing unit, an image signal processor, a sensor hub processor, a communication processor, etc.) that may be operated independently or together with the main processor ED21. The auxiliary processor (ED23) may use less power than the main processor ED21 and may perform specialized functions.

The auxiliary processor ED23 may control functions and/or states related to some of the components (e.g., the display device ED60, the sensor module ED76, the communication module ED90) of the electronic apparatus ED01 instead of the main processor ED21 while the main processor ED21 is in an inactive state (sleep state), or together with the main processor ED21 while the main processor ED21 is in an active state (application execution state). The auxiliary processor ED23 (an image signal processor, a communication processor, etc.) may be implemented as a part of other functionally related components (the camera module ED80, the communication module ED90, etc.).

The memory ED30 may store various data required by components (the processor ED20, the sensor module ED76, etc.) of the electronic apparatus ED01. Data may include, for example, input data and/or output data for software (such as program ED40) and instructions related to the command. The memory ED30 may include a volatile memory ED32 and/or a non-volatile memory ED34.

The program ED40 may be stored as software in the memory ED30 and may include an operating system ED42, middleware ED44, and/or applications ED46.

The input device ED50 may receive commands and/or data to be used in components (such as the processor ED20) of the electronic apparatus ED01 from outside the electronic apparatus ED01 (such as a user). The input device ED50 may include a microphone, a mouse, a keyboard, and/or a digital pen (such as a stylus pen, etc.).

The audio output device ED55 may output an audio signal to the outside of the electronic apparatus ED01. The sound output device ED55 may include a speaker and/or a receiver. The speaker may be used for general purposes, such as multimedia playback or recording playback, and the receiver may be used to receive incoming calls. The receiver may be integrated as part of the speaker or may be implemented as a separate, independent device.

The display device ED60 may visually provide information to the outside of the electronic apparatus ED01. The display device ED60 may include a control circuit for controlling a display, a hologram device, or a projector and a corresponding device. The display device ED60 may include a touch circuitry configured to detect a touch, and/or a sensor circuit configured to measure the intensity of force generated by the touch (such as a pressure sensor).

The audio module ED70 may convert a sound into an electrical signal or, conversely, convert an electrical signal into a sound. The audio module ED70 may acquire a sound through the input device ED50 or may output a sound through a speaker and/or headphone of the sound output device ED55 and/or another electronic apparatus (electronic apparatus ED02, etc.) directly or wirelessly connected to the electronic device ED01.

The sensor module ED76 may detect an operating state (power, temperature, etc.) of the electronic apparatus ED01 or an external environmental state (user state, etc.), and may generate an electrical signal and/or data value corresponding to the sensed state. The sensor module ED76 may include a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, and/or an illuminance sensor.

The interface ED77 may support one or a plurality of designated protocols that may be used by the electronic apparatus ED01 to connect directly or wirelessly with another electronic apparatus (e.g., the electronic apparatus ED02). The interface 2277 may include a High Definition Multimedia Interface (HDMI), a Universal Serial Bus (USB) interface, an SD card interface, and/or an audio interface.

The connection terminal ED78 may include a connector through which the electronic apparatus ED01 may be physically connected to another electronic apparatus (e.g., the electronic apparatus ED02). The connection terminal ED78 may include an HDMI connector, a USB connector, an SD card connector, and/or an audio connector (e.g., a headphone connector).

The haptic module ED79 may convert an electrical signal into a mechanical stimulus (vibration, movement, etc.) or an electrical stimulus that the user may perceive through tactile or kinesthetic sense. The haptic module ED79 may include a motor, a piezoelectric element, and/or an electrical stimulation device.

The camera module ED80 may capture still images and moving images. The camera module ED80 may include a lens assembly including one or a plurality of lenses, the image sensor 1000 of FIG. 1, image signal processors, and/or flashes. The lens assembly included in the camera module ED80 may collect light emitted from an object that is an imaging target.

The power management module ED88 may manage power supplied to the electronic apparatus ED01. The power management module ED88 may be implemented as part of a Power Management Integrated Circuit (PMIC).

The battery ED89 may supply power to components of electronic apparatus ED01. The battery ED89 may include a non-rechargeable primary cell, a rechargeable secondary cell, and/or a fuel cell.

The communication module ED90 may establish a direct (wired) communication channel and/or a wireless communication channel between the electronic apparatus ED01 and other electronic apparatuses (the electronic apparatus ED02, the electronic apparatus ED04, the server ED08, etc.); and may support the performance of communication through the established communication channels. The communication module ED90 may include one or more communication processors that operate independently of the processor ED20 (e.g., an application processor) and support direct communication and/or wireless communication. The communication module ED90 may include a wireless communication module ED92 (a cellular communication module, a short-range wireless communication module, a Global Navigation Satellite System (GNSS, etc.) communication module) and/or a wired communication module ED94 (a Local Area Network (LAN) communication module, or a power line communication module, etc.). Among these communication modules, a corresponding communication module may communicate with other electronic apparatuses through the first network ED98 (a short-range communication network, such as Bluetooth, WiFi Direct, or Infrared Data Association (IrDA)) or the second network ED99 (a telecommunication network, such as a cellular network, the Internet, or a computer network (LAN) and WAN, etc.). The various types of communication modules may be integrated into one component (a single chip, etc.) or implemented as a plurality of components (plural chips) separate from each other. The wireless communication module ED92 may identify and authenticate the electronic apparatus ED01 within a communication network, such as the first network ED98 and/or the second network ED99 by using subscriber information (such as, International Mobile Subscriber Identifier (IMSI)) stored in a subscriber identification module ED96.

The antenna module ED97 may transmit signals and/or power to and from the outside (other electronic apparatuses, etc.). The antenna may include a radiator consisting of a conductive pattern formed on a substrate (PCB, etc.). The antenna module ED97 may include one or multiple antennas. When a plurality of antennas are included, an antenna suitable for a communication method used in a communication network, such as the first network ED98 and/or the second network ED99 may be selected from among the plurality of antennas by the communication module (ED90). Signals and/or power may be transmitted or received between the communication module ED90 and other electronic apparatuses through the selected antenna. In addition to the antenna, other components (RFIC, etc.) may be included as part of the antenna module ED97.

Some of the components are connected to each other through communication methods between peripheral devices (a bus, a General Purpose Input and Output (GPIO), a Serial Peripheral Interface (SPI), a Mobile Industry Processor Interface (MIPI), etc.) and may interchange signals (commands, data, etc.).

Commands or data may be transmitted or received between the electronic apparatus ED01 and the external electronic apparatus ED04 through the server ED08 connected to the second network ED99. The other electronic apparatuses ED02 and ED04 may be the same or different types of the electronic apparatus ED01. All or some of operations performed in the electronic apparatus ED01 may be executed in one or more of the other electronic apparatuses ED02, ED04, and ED08. For example, when the electronic apparatus ED01 needs to perform a function or service, the electronic apparatus ED01 may request one or more other electronic apparatuses to perform part or all function or service instead of executing the function or service itself. One or more other electronic apparatuses receiving the request may execute an additional function or service related to the request, and transmit a result of the execution to the electronic apparatus ED01. For this purpose, cloud computing, distributed computing, and/or client-server computing technologies may be used.

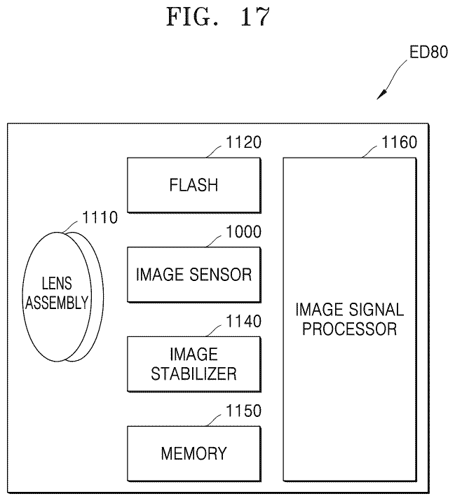

FIG. 17 is a block diagram illustrating the camera module ED80 provided in the electronic apparatus ED01 of FIG. 16. Referring to FIG. 17, the camera module ED80 may include a lens assembly 1110, a flash 1120, an image sensor 1000, an image stabilizer 1140, a memory 1150 (a buffer memory, etc.), and/or an image signal processor 1160. The lens assembly 1110 may collect light emitted from an object that is a target of image capture. The camera module ED80 may include a plurality of lens assemblies 1110, and in this case, the camera module ED80 may be a dual camera, a 360-degree camera, or a spherical camera. Some of the plurality of lens assemblies 1110 may have the same lens properties (angle of view, focal length, autofocus, F number, optical zoom, etc.) or may have different lens properties. The lens assembly 1110 may include a wide-angle lens or a telephoto lens.

The flash 1120 may emit light that is used to enhance light emitted or reflected from an object. The flash 1120 may emit visible light or infrared light. The flash 1120 may include one or a plurality of light-emitting diodes (Red-Green-Blue (RGB)) LED, White LED, Infrared LED, Ultraviolet LED, etc.), and/or a Xenon Lamp. The image sensor 1000 may be the image sensor described with reference to FIG. 1 and may obtain an image corresponding to the object by converting light emitted or reflected from the object and transmitted through the lens assembly 1110 into an electrical signal.

The image stabilizer 1140 may compensate for negative effects of movement in response to a movement of the camera module ED80 or the electronic apparatus 1101 including the camera module ED80 by moving one or more lenses included in the lens assembly 1110 or image sensors 1000 in a specific direction or controlling the operation characteristics of the image sensor 1000 (adjustment of read-out timing, etc.). The image stabilizer 1140 may detect the movement of the camera module ED80 or the electronic apparatus ED01 using a gyro sensor or an acceleration sensor placed inside or outside the camera module ED80. The image stabilizer 1140 may also be implemented optically.

The memory 1150 may store some or all data of an image acquired through the image sensor 1000 for the following image processing task. For example, when multiple images are acquired at high speed, the acquired original data (Bayer-Patterned data, high-resolution data, etc.) may be stored in the memory 1150, and low-resolution images are displayed, afterwards, the original data of the selected (user selection, etc.) image may be transmitted to the image signal processor 1160. The memory 1150 may be integrated into the memory ED30 of the electronic apparatus ED01 or may be configured as a separate memory that operates independently.

The image signal processor 1160 may perform image processing on images acquired through the image sensor 1000 or image data stored in the memory 1150. Image processing may include a depth map creation, a 3D modeling, a panorama creation, a feature point extraction, an image compositing, and/or an image compensation (noise reduction, resolution adjustment, brightness adjustment, blurring, sharpening, softening, etc.). The image signal processor 1160 may perform control (exposure time control, lead-out timing control, etc.) on components (such as the image sensor 1000) included in the camera module ED80. Also, the image signal processor 1160 may generate a full-color image by performing a demosaicing algorithm. For example, when performing a demosaicing algorithm to generate a full-color image, the image signal processor 1160 may restore most of spatial resolution information by using an image signal of a green channel or yellow channel having a high spatial sampling rate.

An image processed by the image signal processor 1160 may be re-stored in the memory 1150 for further processing or provided to an external component of the camera module ED80 (the memory ED30, the display device ED60, the electronic apparatus ED02, the electronic apparatus ED04, the server ED08, etc.). The image signal processor 1160 may be integrated into the processor ED20 or may be configured as a separate processor that operates independently of the processor ED20. When the image signal processor 1160 is configured as a separate processor from the processor ED20, an image processed by the image signal processor 1160 undergoes additional image processing by the processor ED20 and then is displayed on the display device ED60.

Also, the image signal processor 1160 may independently receive two output signals from adjacent photo-sensing cells within each pixel or sub-pixel of the image sensor 1000 and may generate an autofocus signal from a difference between the two output signals. The image signal processor 1160 may control the lens assembly 1110 so that a focus of the lens assembly 1110 is accurately aligned with a surface of the image sensor 1000 based on an autofocus signal.

The electronic apparatus ED01 may further include one or more camera modules, each having different properties or functions. This camera module may also include a similar configuration to the camera module ED80 of FIG. 17, and an image sensor provided therein may be implemented as a CCD sensor and/or CMOS sensor and may include one or more sensors selected from image sensors with different properties, such as an RGB sensor, a BW (Black and White) sensor, an IR sensor, or a UV sensor. In this case, one of the plurality of camera modules ED80 may be a wide-angle camera and the other may be a telephoto camera. Similarly, one of the plurality of camera modules ED80 may be a front camera and the other may be a rear camera.

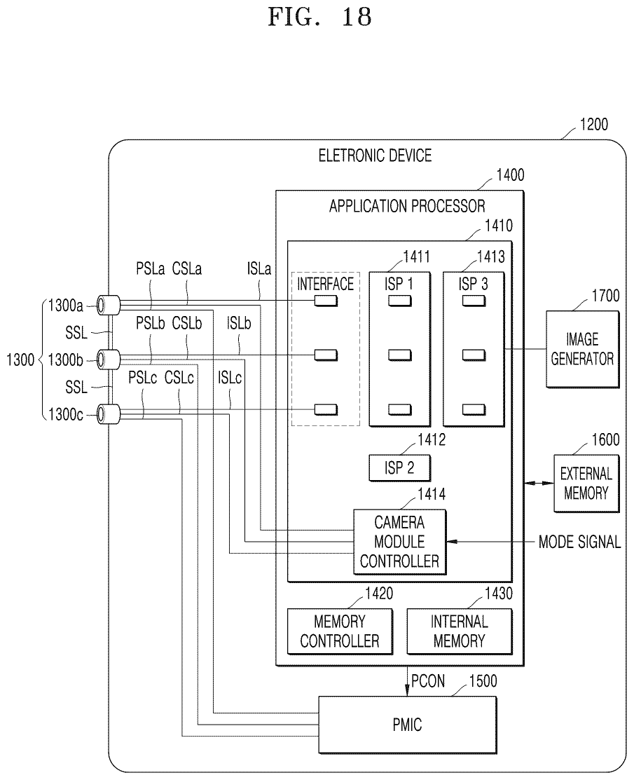

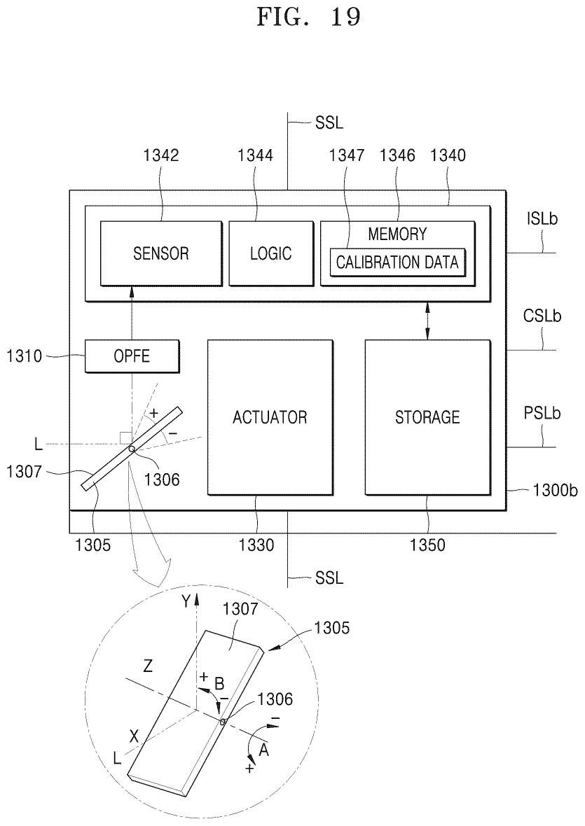

FIG. 18 is a block diagram of an electronic device 1200 including a multi-camera module, and FIG. 19 is a detailed block diagram of one camera module of the electronic device 1200 shown in FIG. 18.

Referring to FIG. 18, the electronic device 1200 may include a camera module group 1300, an application processor 1400, a power management integrated circuit (PMIC) 1500, an external memory 1600, and an image generator 1700.

The camera module group 1300 may include a plurality of camera modules 1300a, 1300b, and 1300c. Although the drawing shows an example embodiment in which three camera modules 1300a, 1300b, and 1300c are arranged, embodiments are not limited thereto. In some embodiments, the camera module group 1300 may be modified to include only two camera modules. Also, in some embodiments, the camera module group 1300 may be modified to include n camera modules (n is a natural number of 4 or more).

Hereinafter, a configuration of the camera module 1300b will be described in more detail with reference to FIG. 19, but the following description may be equally applied to other camera modules 1300a and 1300c depending on the embodiment.

Referring to FIG. 19, the camera module 1300b may include a prism 1305, an optical path folding element (hereinafter referred to as “OPFE”) 1310, an actuator 1330, an image sensing device 1340, and a storage unit 1350.

The prism 1305 may include a reflective surface 1307 of a light-reflecting material to change a path of light L incident from the outside.

In some embodiments, the prism 1305 may change the path of light L incident in the first direction X to the second direction Y perpendicular to the first direction X. In addition, the prism 1305 may change the path of the light L incident in the first direction X to the second direction Y perpendicular to the first direction X by rotating the reflecting surface 1307 of the light reflecting material in a direction A about the central axis 1306 or rotating the central axis 1306 in a direction B. At this time, the OPFE 1310 may also move in the third direction Z perpendicular to the first direction X and the second direction Y.

In some embodiments, as shown in FIG. 19, a maximum rotation angle of the prism 1305 in the direction A may be less than 15 degrees in the plus (+) A direction and greater than 15 degrees in the minus (−) A direction, but embodiments are not limited thereto.

In some embodiments, the prism 1305 may move about 20 degrees in the plus (+) or minus (−) B direction, between 10 degrees and 20 degrees, or between 15 degrees and 20 degrees. Here, the moving angle may be the same angle in the plus (+) or minus (−) B direction or may be moved to almost the same angle within a range of about 1 degree.

In some embodiments, the prism 1305 may move the reflective surface 1307 of the light reflecting material in a third direction (e.g., the Z direction) parallel to the direction of extension of the central axis 1306.

The OPFE 1310 may include, for example, an optical lens including m groups (where m is a natural number). The m optical lenses may move in the second direction (Y) to change an optical zoom ratio of the camera module 1300b. For example, assuming that a basic optical zoom magnification ratio of the camera module 1300b is Z, when the m optical lenses included in the OPFE 1310 is moved, the optical zoom magnification ratio of the camera module 1300b may be changed to 3Z, 5Z, 10Z or higher.

The actuator 1330 may move the OPFE 1310 or an optical lens (hereinafter referred to as an optical lens) to a specific position. For example, the actuator 1330 may adjust the position of the optical lens so that the image sensor 1342 is located at a focal length of the optical lens for accurate sensing.

The image sensing device 1340 may include an image sensor 1342, a control logic 1344, and a memory 1346. The image sensor 1342 may sense an image of a sensing object using light (L) provided through an optical lens. The control logic 1344 may control an overall operation of the camera module 1300b. For example, the control logic 1344 may control the operation of the camera module 1300b according to a control signal provided through the control signal line CSLb.

As an example, the image sensor 1342 may include a color separation lens array or a nano-photonic lens array described above. The image sensor 1342 may receive more signals separated by wavelength for each pixel by using a nanostructure-based color separation lens array. Due to this effect, an amount of light required to create a high-quality image at high resolution and low luminance may be secured.

The memory 1346 may store information necessary for the operation of the camera module 1300b, such as calibration data 1347. The calibration data 1347 may include information necessary to generate image data using light L provided from the outside through the camera module 1300b. The calibration data 1347 may include, for example, information about the degree of rotation described above, information about a focal length, and information about an optical axis. When the camera module 1300b is implemented as a multi-state camera in which a focal length is changed depending on the position of the optical lens, the calibration data 1347 may include information related to a focal length value for each position (or state) and an auto focusing of the optical lens.

The storage unit 1350 may store image data sensed through the image sensor 1342. The storage unit 1350 may be placed outside the image sensing device 1340 and may be implemented in a stacked form with a sensor chip constituting the image sensing device 1340. In some embodiments, the storage unit 1350 may be implemented as an Electrically Erasable Programmable Read-Only Memory (EEPROM), but embodiments are not limited thereto.

Referring to FIGS. 18 and 19 together, in some embodiments, each of the plurality of camera modules 1300a, 1300b, and 1300c may include the actuator 1330. Accordingly, each of the plurality of camera modules 1300a, 1300b, and 1300c may include the same or different calibration data 1347 according to the operation of the actuator 1330 included therein.

In some embodiments, one camera module (e.g., 1300b) of the plurality of camera modules 1300a, 1300b, and 1300c may be a folded lens including the prism 1305 and the OPFE 1310 described above. type camera module, and the remaining camera modules (e.g., 1300a and 1300b) may be vertical type camera modules that do not include the prism 1305 and the OPFE 1310, but embodiments are limited thereto.

In some embodiments, one camera module (e.g., 1300c) among the plurality of camera modules (1300a, 1300b, and 1300c) may be, for example, a vertical type of depth camera that extracts depth information using Infrared Ray (IR).

In some embodiments, at least two camera modules (e.g., 1300a and 1300b) among the plurality of camera modules 1300a, 1300b, and 1300c may have different fields of view (viewing angle). In this case, for example, the optical lenses of at least two camera modules (for example, 1300a and 1300b) among the plurality of camera modules (1300a, 1300b, and 1300c) may be different from each other, but are not limited thereto.

Additionally, in some embodiments, the viewing angles of each of the plurality of camera modules 1300a, 1300b, and 1300c may be different from each other. In this case, optical lenses included in each of the plurality of camera modules 1300a, 1300b, and 1300c may also be different from each other, but embodiments are not limited thereto.

In some embodiments, each of the plurality of camera modules 1300a, 1300b, and 1300c may be disposed to be physically separated from each other. That is, rather than dividing the sensing region of one image sensor 1342 into multiple camera modules 1300a, 1300b, and 1300c, an independent image sensor 1342 may be disposed inside each of the plurality of camera modules 1300a, 1300b, and 1300c.

Referring again to FIG. 18, the application processor 1400 may include

an image processing device 1410, a memory controller 1420, and an internal memory 1430. The application processor 1400 may be implemented separately from the plurality of camera modules 1300a, 1300b, and 1300c. For example, the application processor 1400 and the plurality of camera modules 1300a, 1300b, and 1300c may be implemented separately as separate semiconductor chips.

The image processing device 1410 may include a plurality of image processors 1411, 1412, and 1413, and a camera module controller 1414.

Image data generated from each of the camera modules 1300a, 1300b, and 1300c may be provided to the image processing device 1410 through separate image signal lines (ISLa, ISLb, and ISLc). Such image data transmission may be performed using, for example, a Camera Serial Interface (CSI) based on Mobile Industry Processor Interface (MIPI), but embodiments are not limited thereto.

Image data transmitted to the image processing device 1410 may be stored in the external memory 1600 before being transmitted to the image processors 1411 and 1412. Image data stored in the external memory 1600 may be provided to the image processor 1411 and/or the image processor 1412. The image processor 1411 may correct received image data to generate a video. The image processor 1412 may correct received image data to generate a still image. For example, the image processors 1411 and 1412 may perform preprocessing operations, such as color correction and gamma correction on image data.

The image processor 1411 may include sub-processors. When the number of sub-processors is equal to the number of camera modules 1300a, 1300b, and 1300c, each of the sub-processors may process image data provided from one camera module. When the number of sub-processors is less than the number of camera modules 1300a, 1300b, and 1300c, at least one of the sub-processors may process image data provided from a plurality of camera modules using a timing sharing process. Image data processed by the image processor 1411 and/or the image processor 1412 may be stored in the external memory 1600 before being transmitted to the image processor 1413. Image data stored in the external memory 1600 may be transmitted to the image processor 1412. The image processor 1412 may perform post-processing operations such as noise correction and sharpening correction on the image data.

Image data processed by the image processor 1413 may be provided to the image generator 1700. The image generator 1700 may generate a final image using image data provided from the image processor 1413 according to image generating information or a mode signal.

Specifically, the image generator 1700 may generate an output image by merging at least some of the image data generated from the camera modules 1300a, 1300b, and 1300c having different viewing angles from each other according to image generation information or mode signal. Also, the image generator 1700 may generate an output image by selecting one of the image data generated from the camera modules 1300a, 1300b, and 1300c having different viewing angles from each other according to the image generation information or mode signal.

In some embodiments, the image generation information may include a zoom signal or zoom factor. Also, in some embodiments, the mode signal may be, for example, a signal based on a mode selected by the user.

When the image generation information is a zoom signal (zoom factor) and each of the camera modules 1300a, 1300b, and 1300c has a different observation field (viewing angle), the image generator 1700 performs different operations depending on the type of zoom signal. For example, when the zoom signal is the first signal, the image data output from the camera module 1300a and the image data output from the camera module 1300c are merged, and then, an output image may be generated by using the merged image data and the image data output from the camera module 1300b that is not used for merging. When the zoom signal is a second signal different from the first signal, the image generator 1700 does not merge the image data but may generate an output image by selecting one of the image data output from each camera module 1300a, 1300b, and 1300c. However, embodiments are not limited thereto, and the method of processing image data may be modified and implemented as necessary.

The camera module controller 1414 may provide control signals to each camera module 1300a, 1300b, and 1300c. Control signals generated from the camera module controller 1414 may be provided to the corresponding camera modules 1300a, 1300b, and 1300c through separate control signal lines CSLa, CSLb, and CSLc.

In some embodiments, a control signal provided from the camera module controller 1414 to the plurality of camera modules 1300a, 1300b, and 1300c may include mode information according to a mode signal. Based on the mode information, the plurality of camera modules 1300a, 1300b, and 1300c may operate in a first operation mode and a second operation mode in relation to a sensing speed.

In the first operation mode, the plurality of camera modules 1300a, 1300b, and 1300c may generate an image signal at a first speed (for example, generate an image signal at a first frame rate), encode (e.g., encode the image signal at a second frame rate higher than the first frame rate) the image signal at a second speed higher than the first speed, and transmit the encoded image signal to the application processor 1400. At this time, the second speed may be 30 times or less than the first speed.

The application processor 1400 may store the received image signal, that is, an encoded image signal in the internal memory 1430 provided therein or the storage 1600 outside the application processor 1400, thereafter, decode the encoded image signal by reading the encoded image signal from the internal memory 1430 or the storage 1600, and display the image data generated based on the decoded image signal. For example, the image processors 1411 and 1412 of the image processing device 1410 may perform decoding and may also perform image processing on the decoded image signal.

In the second operation mode, the plurality of camera modules 1300a, 1300b, and 1300c may generate image signals at a third speed lower than the first speed (for example, generate an image signal at a third frame rate lower than the first frame rate) and transmit the image signal to the application processor 1400. The image signal provided to the application processor 1400 may be an unencoded signal. The application processor 1400 may perform image processing on a received image signal or store the image signal in the internal memory 1430 or storage 1600.

The PMIC 1500 may supply power, for example, a power supply voltage, to each of the plurality of camera modules 1300a, 1300b, and 1300c. For example, the PMIC 1500, under the control of the application processor 1400, may supply first power to the camera module 1300a through a power signal line PSLa, supply second power to the camera module 1300b through a power signal line PSLb, and supply third power to the camera module 1300c through a power signal line PSLc.

The PMIC 1500 may generate power corresponding to each of the plurality of camera modules 1300a, 1300b, and 1300c in response to a power control signal PCON from the application processor 1400 and may also adjust a power level. The power control signal PCON may include a power control signal for each operation mode of the plurality of camera modules 1300a, 1300b, and 1300c. For example, the operation mode may include a low power mode, and in this case, the power control signal PCON may include information about the camera module operating in a low power mode and a set power level. The levels of power provided to each of the plurality of camera modules 1300a, 1300b, and 1300c may be the same or different from each other. Additionally, the level of power may be dynamically changed.

According to the disclosed embodiments, the light utilization efficiency of an image sensor may be improved by applying an organic photoelectric conversion layer including a nano-photonic lens array and a singlet fission material. As light utilization efficiency improves, it is possible to reduce the size of one pixel of an image sensor or the size of independent light sensing cells within a pixel. Therefore, an image sensor with higher resolution may be provided.

Additionally, according to the embodiments, the balance of each color of the image sensor may be improved by applying an organic photoelectric conversion layer including a nano-photonic lens array and a singlet fission material.

While an image sensor including a nano-photonic lens array and an electronic apparatus including the same have been described with reference to the embodiments shown in the drawings, it will be understood by those of ordinary skill in the art that various changes in form and details may be made therein without departing from the spirit and scope of the disclosure. The embodiments should be considered in descriptive sense only and not for purposes of limitation. Therefore, the scope of the disclosure is defined not by the detailed description of the disclosure but by the appended claims, and all differences within the scope will be construed as being included in the disclosure.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An image sensor comprising:
a sensor substrate comprising a plurality of pixels;
a nano-photonic lens array comprising a plurality of nanostructures configured to separate light based on wavelength of the light and focus the light onto a corresponding pixel among the plurality of pixels; and
an organic photoelectric conversion layer between the sensor substrate and the nano-photonic lens array, the organic photoelectric conversion layer being configured to absorb photons and multiply carriers.

2. The image sensor of claim 1, wherein the organic photoelectric conversion layer comprises a singlet fission material.

3. The image sensor of claim 2, wherein the singlet fission material comprises polyacene, rylene, rubrene, biradicaloid, or any combination thereof.

4. The image sensor of claim 3, wherein the polyacene comprises anthracene, tetracene, pentacene, or any combination thereof.

5. The image sensor of claim 3, wherein the rylene comprises perylene, terylene, or any combination thereof.

6. The image sensor of claim 1, further comprising an intermediate layer between the sensor substrate and the organic photoelectric conversion layer, the intermediate layer being configured to prevent recombination of charge-electron pairs, wherein a thickness of the intermediate layer is in a range from 1 nm to 10 nm.

7. The image sensor of claim 1, further comprising a spacer layer between the organic photoelectric conversion layer and the nano-photonic lens array, wherein a thickness of the spacer layer is in a range from 500 nm to 1000 nm.

8. The image sensor of claim 1, wherein a thickness of the organic photoelectric conversion layer is in a range from 10 nm to 100 nm.

9. The image sensor of claim 7, further comprising a color filter layer between the organic photoelectric conversion layer and the spacer layer, wherein the color filter layer comprises a plurality of color filters.

10. The image sensor of claim 9, wherein the plurality of color filters are organic color filters.

11. The image sensor of claim 10, further comprising a barrier wall between the plurality of color filters.

12. The image sensor of claim 11, wherein the barrier wall extends to a certain portion of the organic photoelectric conversion layer.

13. The image sensor of claim 12, wherein the organic photoelectric conversion layer comprises a plurality of organic photoelectric conversion elements, and
wherein the plurality of organic photoelectric conversion elements have different thicknesses based on a color of a corresponding color filter.

14. The image sensor of claim 9, wherein the plurality of color filters are inorganic color filters.

15. The image sensor of claim 1, wherein each of the plurality of nanostructures comprises a first nanostructure and a second nanostructure, and wherein the first nanostructure and the second nanostructure are arranged in a multi-layer structure.

16. The image sensor of claim 1, further comprising an anti-reflection film on the nano-photonic lens array.

17. An electronic apparatus comprising:
an image sensor configured to convert an optical image into an electrical signal; and
a processor configured to control operation of the image sensor and store and output signals generated by the image sensor,
wherein the image sensor comprises:
a sensor substrate comprising a plurality of pixels;
a nano-photonic lens array comprising a plurality of nanostructures configured to separate light based on wavelength of the light and focus the light onto a corresponding pixel among the plurality of pixels; and
an organic photoelectric conversion layer between the sensor substrate and the nano-photonic lens array, the organic photoelectric conversion layer being configured to absorb photons and multiply carriers.

18. The electronic apparatus of claim 17, wherein the organic photoelectric conversion layer comprises a singlet fission material.

19. The electronic apparatus of claim 18, wherein the singlet fission material comprises polyacene, rylene, rubrene, biradicaloid, or any combination thereof.

20. The electronic apparatus of claim 19, wherein the polyacene comprises anthracene, tetracene, pentacene, or any combination thereof, and
wherein the rylene comprises perylene, terylene, or any combination thereof.

21. An image sensor comprising:
a sensor substrate comprising a plurality of pixels;
a nano-photonic lens array comprising a plurality of nanostructures configured to separate light based on wavelength of the light and focus the light onto a corresponding pixel among the plurality of pixels; and
an organic photoelectric conversion layer between the sensor substrate and the nano-photonic lens array, the organic photoelectric conversion layer comprising a material configured to absorb photons and increase a number of excitons.

22. The image sensor of claim 21, wherein the organic photoelectric conversion layer comprises a first organic photoelectric conversion element corresponding to a first color filter, a second organic photoelectric conversion element corresponding to a second color filter, a third organic photoelectric conversion element corresponding to a third color filter, and a fourth organic photoelectric conversion element corresponding to a fourth color filter, and
wherein at least two of a thickness of the first organic photoelectric conversion element, a thickness of the second organic photoelectric conversion element, a thickness of the third organic photoelectric conversion element and a thickness of a fourth organic photoelectric conversion element are different from each other.
